(19) United States
(12) Patent Application Publication
(10) Pub. No.: US 2026/0086942 A1
(43) Pub. Date: Mar. 26, 2026

(54) DRAM FOR CACHES

(71) Applicant: Rambus Inc., San Jose, CA (US)

(72) Inventors: Brent Steven HAUKNESS, Sunnyvale, CA (US); Michael Raymond MILLER, Raleigh, NC (US); Steven C. WOO, Saratoga, CA (US); Wendy ELSASSER, Austin, TX (US)

(21) Appl. No.: 19/108,399

(22) PCT Filed: Sep. 5, 2023
(86) PCT No.: PCT/US2023/031973

§ 371 Date: Mar. 3, 2025

Related U.S. Application Data
(60) Provisional application No. 63/405,145, filed on Sep. 9, 2022.
(60) Provisional application No. 63/431,276, filed on Dec. 8, 2022.

(51) Int. Cl. G06F 12/0802; G06F 11/10

(52) U.S. Cl. CPC G06F 12/0802; G06F 11/1064; G06F 2212/1032; G06F 2212/22

(57) ABSTRACT

In response to some access commands, a DRAM device is configured to receive cache tag query values and to compare stored cache tag values with the cache tag query values. A hit/miss (HM) interface/bus may indicate the result of the cache tag compare and stored cache line status bits to a controller. Based on the cache tag compare results and status bits of the associated cache line, the timing and content of the data responses and/or compare responses these access commands may be varied. The controller is configured to, based on the indicated results of the cache tag compare and stored cache line status bits, expect the varied timing and content in response to the access commands transmitted by the controller. In an embodiment, the DRAM protects the stored cache tag values with an error detection and correction code.

### BRIEF DESCRIPTION OF THE DRAWINGS

FIG. 1 is a block diagram illustrating a memory system.

FIGS. 2A-2B are diagrams illustrating example data placements within rows of a dynamic random access memory (DRAM).

FIGS. 3A-3D illustrate varying bus communications for commands based on cache tag access results.

FIGS. 4A-4F illustrate example timing relationships.

FIG. 5 is a block diagram illustrating a memory system.

FIG. 6 is a timing diagram illustrating an example variable relationship between read commands and tag compare results.

FIG. 7 is a timing diagram illustrating an example flush buffer function.

FIG. 8 is a flowchart illustrating a method of operating a memory component.

FIG. 9 is a flowchart illustrating a method of operating a memory component to protect cache tag data.

FIG. 10 is a flowchart illustrating a method of varying read access response timing.

FIG. 11 is a flowchart illustrating a method of varying write access response timing.

FIG. 12 is a flowchart illustrating a method of receiving cache line data transmitted with variable read access timing.

FIG. 13 is a flowchart illustrating a method of varying read access response content.

FIG. 14 is a flowchart illustrating a method of managing a flush buffer.

FIG. 15 is a flowchart illustrating a method of operating a memory controller.

FIGS. 16A-16B are a flowcharts illustrating a methods of correcting a cache tag errors.

FIGS. 17A-17B are flowcharts illustrating a methods of responding to a dirty miss.

FIG. 18 is a flowchart illustrating a method of varying access response timing.

FIG. 19 is a block diagram illustrating a processing system.

### DETAILED DESCRIPTION OF THE EMBODIMENTS

In an embodiment, a dynamic random access memory (DRAM) device includes functions configured to aid with operating the DRAM device as part of data caching functions. In response to some access commands, the DRAM device is configured to receive cache tag query values and to compare stored cache tag values with the cache tag query values. A hit/miss (HM) interface/bus may indicate the result of the cache tag compare and stored cache line status bits to a controller. Based on the cache tag compare results and status bits of the associated cache line, the timing and content of the data responses and/or compare responses these access commands may be varied. The controller is configured to, based on the indicated results of the cache tag compare and stored cache line status bits, expect the varied timing and content in response to the access commands transmitted by the controller. In an embodiment, the DRAM protects the stored cache tag values with an error detection and correction code.

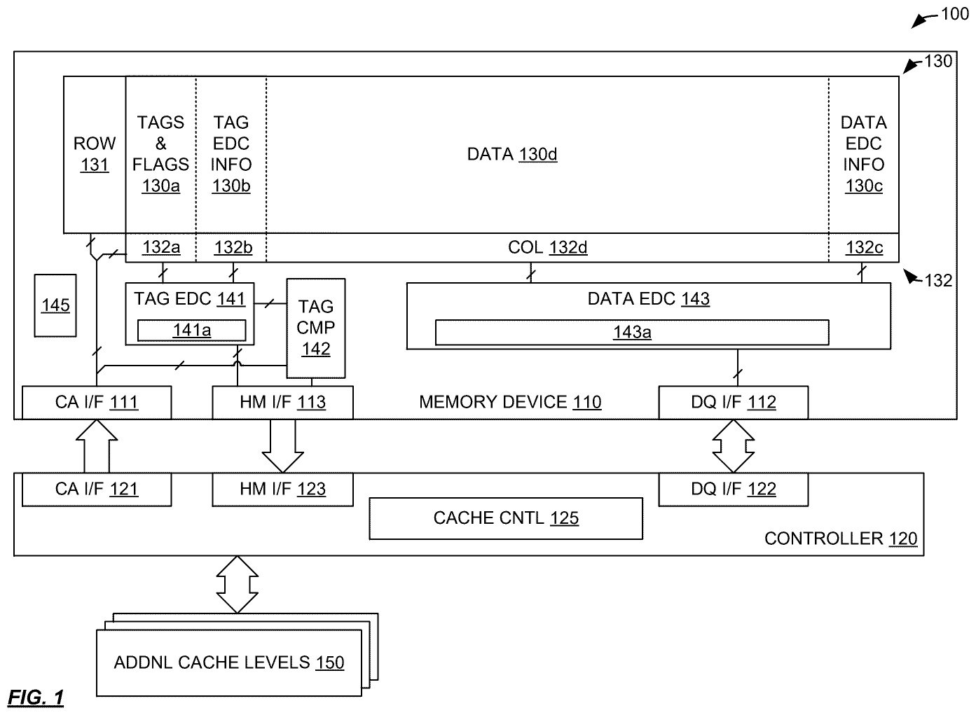

FIG. 1 is a block diagram illustrating a memory system. In FIG. 1, memory system 100 comprises memory device 110 and memory controller 120. Memory device 110 includes command/address (CA) interface 111, data (DQ) interface 112, hit/miss (HM) interface 113, memory array 130, row circuitry 131, column circuitry 132, tag error detection and correction (EDC) circuitry 141, tag compare circuitry 142, data EDC circuitry 143, and control circuitry 145. The rows and columns of memory array 130 may be organized into rows and columns of memory array tiles (MATs). Memory controller 120 includes CA interface 121, DQ interface 122, hit/miss (HM) interface 123, and cache control circuitry 125. Controller 120 is operatively coupled to additional cache levels 150, main memory (not shown in FIG. 1), and/or backing store (not shown in FIG. 1).

CA interface 121 of controller 120 is operatively coupled to CA interface 111 of memory device 110. CA interface 121 of controller 120 is operatively coupled to CA interface 111 of memory device 110 to at least communicate, from controller 120, commands, addresses, and cache tag query values to memory device 110. DQ interface 122 of controller 120 is operatively coupled to DQ interface 112 of memory device 110. DQ interface 122 of controller 120 is operatively coupled to DQ interface 112 of memory device 110 to communicate data (e.g., cache lines, dirty cache lines, cache line fill data) between controller 120 and memory device 110. HM interface 123 of controller 120 is operatively coupled to HM interface 113 memory device 110. HM interface 123 of controller 120 is operatively coupled to HM interface 113 memory device 110 to at least communicate, from memory device 110, indicators of a cache tag compare result (i.e., hit or miss), and whether a cache access was to a clean or dirty cache line (e.g., cache flag indicators) to controller 120.

Memory controller 120 and memory device 110 may be integrated circuit type devices, such as are commonly referred to as “chips”. A memory controller, such as memory controller 120, manages the flow of data going to and from memory devices and/or memory modules. Memory device 110 may be a standalone device, or may be a component of a memory module such as a DIMM module used in servers. Memory device 110 may be, or be part of, a component having a “stack” of memory devices. Memory device 110 may be a device that adheres to, or is compatible with, a dynamic random access memory (DRAM) specification. A memory controller can be a separate, standalone chip, or integrated into another chip. For example, a memory controller 120 may be included on a single die with a microprocessor, included as a chip co-packaged with one or more microprocessor chips, included as part of a more complex integrated circuit system such as a block of a system on a chip (SOC), or be remotely coupled to one or more microprocessors via a fabric interconnect or other type of interconnect.

CA interface 111 of memory device 110 is operatively coupled to row circuitry 131, column circuitry 132, and tag compare circuitry 142. CA interface 111 is operatively coupled to row circuitry 131 to at least to activate rows in memory array 130. CA interface 111 is operatively coupled to column circuitry 132 to at least sense values from activated rows, and to decode and provide the values of selected columns to other circuitry of memory device 110 (e.g., data EDC circuitry 143, tag EDC circuitry 141, DQ interface 112, etc.) CA interface 111 is operatively coupled to column circuitry 132 to at least provide tag compare circuitry 142 with tag query values indicated by commands.

Memory array 130 of memory device 110 is logically subdivided into column groups 130a-130d (or MAT groups, columns of MATs, sections, assignments, and/or associations). Column group 130a is to store cache tags and cache flags. Column group 130b is to store tag EDC information. Column group 130c is to store cache line data (a.k.a., cache line) EDC information. Column group 130d is to store cache lines.

Column circuitry 132 is subdivided into column circuitry group 132a-132d that may have different decoding functions. Column circuitry group 132a is to decode a column address and provide the addressed cache tags and cache flags to tag EDC circuitry 141. Likewise, column circuitry group 132b is to decode the column address and provide the addressed tag EDC information to tag EDC circuitry 141. Column circuitry group 132c is to is to decode the column address and provide the addressed cache line EDC information to data EDC circuitry 143. Column circuitry group 132d is to decode the column address and provide the addressed cache line to data EDC circuitry 143.

Tag EDC circuitry 141 is operatively coupled to tags and flags column circuitry group 132a, tag EDC information column circuitry group 132b, tag compare circuitry 142, and HM interface 113. Tag EDC circuitry 141 is operatively coupled to tags and flags column circuitry group 132a to receive, from cache tags and flags column group 130a and via cache tags and flags column circuitry group 132a, stored cache tag and cache flag values addressed by a command. Tag EDC circuitry 141 is operatively coupled to tag EDC information column circuitry group 132b to receive, from tag EDC information column group 130b and via tag EDC information column circuitry group 132b, stored cache tag EDC information addressed by the command. Tag EDC circuitry 141 may use the received cache tag EDC information to check and/or correct corresponding cache tag and flag values that were accessed in response to the command. Tag EDC circuitry 141 may include one or more registers 141a to store checked and/or corrected cache tag and flag values. Tag EDC circuitry 141 may include one or more registers 141a to store checked and/or corrected cache tag and flag values while other circuitry performs other functions (e.g., tag compare circuitry 142, HM I/F 113) or is waiting for certain conditions to occur (e.g., waiting for an open and/or corresponding time slot on HM I/F 113). Tag EDC circuitry 141 may provide the checked and/or corrected cache tag and flag values to tag compare circuitry 142 and HM interface 113.

Data EDC circuitry 143 is operatively coupled to data EDC column circuitry group 132c, data column circuitry group 132d, and DQ interface 112. Data EDC circuitry 143 is operatively coupled to data EDC column circuitry group 132c to receive, from data EDC column group 130c and via data EDC column circuitry group 132c, stored data EDC information addressed by the command. Data EDC circuitry 143 is operatively coupled to data column circuitry group 132d to receive, from cache line data column group 130d and via cache line data column circuitry group 132d, stored cache line data addressed by the command. Data EDC circuitry 143 may use the received data EDC information to check and/or correct corresponding cache line data that was accessed in response to the command. Data EDC circuitry 143 may include one or more registers 143a to store checked and/or corrected cache line data while other circuitry performs other functions (e.g., tag compare circuitry 142) or is waiting for certain conditions to occur (e.g., waiting for an open and/or corresponding time slot on DQ I/F 112). Data EDC circuitry 143 may provide the checked and/or corrected cache line data to DQ interface 112.

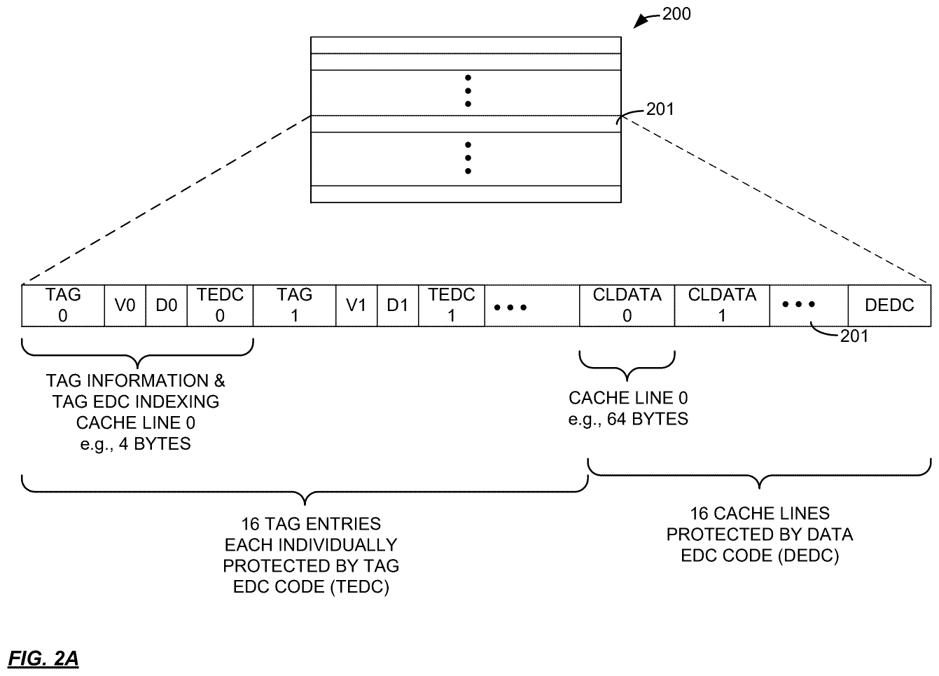

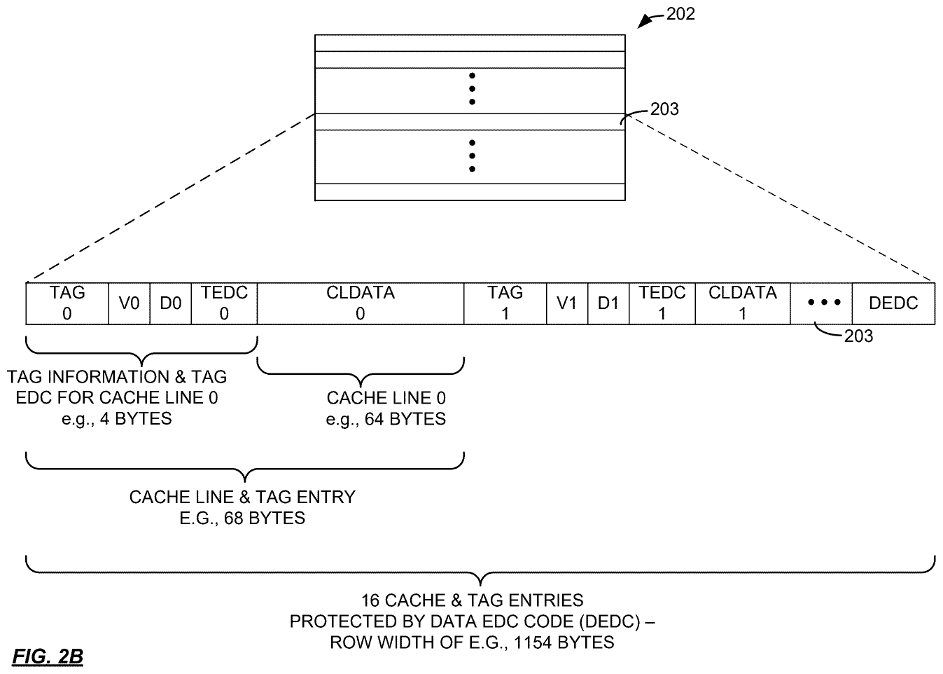

FIGS. 2A-2B are diagrams illustrating example data placements within rows of a dynamic random access memory (DRAM). In FIG. 2A, the data placement of cache tags, flags, and cache line data into the rows of memory bank 200 are illustrated. In particular, the example data placement into row 201 of memory bank 200 is illustrated. In FIG. 2A, the tag, flag, and tag EDC information for the cache lines stored in row 201 is illustrated starting at the leftmost position in row 201 starting with the tag (TAG0), flag (V0, D0), and EDC information (TEDC0) for cache line 0, then proceeding to the next position to the right with the tag (TAG1), flag (V1, D1), and EDC information (TEDC1) for cache line 1, and so on. To the right of the tag, flag, and EDC information for the cache lines stored in row 201, the cache line data starts with the data for cache line 0 (CLDATA0). To the right of cache line 0 is the data for cache line 1 (CLDATA1), and so on. To the right of the cache line data stored in row 201, is the data EDC information (DEDC). The data EDC information is illustrated in the rightmost locations of row 201.

In FIG. 2B, the data placement of cache tags, flags, and cache line data into the rows of memory bank 202 are illustrated. In particular, the example data placement into row 203 of memory bank 202 is illustrated. In FIG. 2B, the tag, flag, and tag EDC information for the cache lines stored in row 203 is illustrated starting at the leftmost position in row 203 starting with the tag (TAG0), flag (V0, D0), EDC information (TEDC0), and cache line data (CLDATA0) for cache line 0, then proceeding to the next position to the right with the tag (TAG1), flag (V1, D1), EDC information (TEDC1), and cache line data (CLDATA1) for cache line 1, and so on. To the right of the tag, flag, EDC information, and cache line data for the cache lines stored in row 203 is the data EDC information (DEDC). The data EDC information is illustrated in the rightmost locations of row 203.

Returning now to FIG. 1, CA interface 121 of memory controller 120 is operatively coupled to CA interface 111 of memory device 110. CA interface 121 is operatively coupled to CA interface 111 to communicate commands, addresses (e.g., row and column addresses), and tag query values from memory controller 120 to memory device 110. In an embodiment, the commands communicated from memory controller 120 to memory device 110 include traditional row operations (e.g., activate and refresh), column operations (e.g., read and write), and at least one command that combines row and column operations. For example, controller 120 may transmit, and memory device 110 receive a combined row and column command that activates an addressed row, reads a set of addressed data columns from the activated row, and compares a tag value retrieved from memory array 130 (and tags and flags column group 130a, in particular) to a tag query value specified by the command (hereinafter, e.g., an Activate-Read command—ACTRD or an Activate-Write—ACTWR).

In an embodiment, controller 120 may transmit, to memory device 110 and via CA interface 121 and CA interface 111, an ACTRD or ACTWR command to access a cache line and its associated tags in memory array 130 for reading or writing the cache line, respectively. A cache tag query value is also transmitted in association with the ACTRD and ACTWR commands. Table 1 illustrates an example command/address/tag encoding for an example ACTRD command (an ACTWR may have a similar encoding). In Table 1: “R” stands for rising edge of the clock; “F” stands for the falling edge of the clock; the tag query value is specified by the bits T0-T17 (or less); the column address is specified by the bits CA0-CA10 (or less); the bank address is specified by bits BA0-BA4 (or less); and the row address is specified by RA0-RA15 (or less).

TABLE 1

| CMD | CK | CA0 | CA1 | CA2 | CA3 | CA4 | CA5 | CA6 | CA7 | CA8 | CA9 | CA10 |
|---|---|---|---|---|---|---|---|---|---|---|---|---|
| Activate- | R | L | H | H | L | SID0/V | SID1/V | BA0 | BA1 | BA2 | BA3 | BA4 |
| Read | F | H | H | L | RA8 | RA9 | RA10 | RA11 | RA12 | RA13/V | RA14 V | RA15 V |
| (ACTRD) | R | H | H | RA0 | RA1 | RA2 | RA3 | RA4 | RA5 | RA6 | RA7 | V |
| | F | H | L | H | L | L | CA0 | CA1 | CA2 | CA3 | CA4 | CA5 |
| | R | H | H | T0 | T1 | T2 | T3 | T4 | T5 | T6 | T7 | T8 |
| | F | H | L | T9 | T10 | T11 | T12 | T13 | T14 | T15 | T16 | T17 |

In an embodiment, cache control circuitry 125 may control memory controller 120 to issue a cache access operation in the form of a combined column and row command (e.g., ACTRD or ACTWR). In addition to a row address and column address (e.g., decoded by row circuitry 131 and column circuitry 132, respectively), the cache access command communicates a tag query value (e.g., T0-T17). In other words, the tag query value corresponds to a tag value that the cache access operation is seeking to compare to a stored tag value to determine whether the cache line corresponding to the tag query value is present in memory device 110 at the specified address (row, bank, and column). In response to the cache access command, memory device 110 activates the addressed row into row sense amplifiers (e.g., in memory array 130), selects those columns associated with the received column address, and provides the stored values at those addressed columns to at least tag EDC circuitry 141 and data EDC circuitry 143.

If tag compare circuitry 142 finds the tag query value matches (i.e., is equal to) the stored tag value in memory array 130 at the address communicated by (or in association with) the cache access command, and the “valid” flag indicates the cache entry is valid, it is termed a cache “hit” and the cache line that cache control circuitry 125 is seeking to read from memory device 110 is present and valid in memory array 130. Based on the cache hit, memory device 110 transmits a “hit” indicator to controller 120 via HM interface 113 and HM interface 123. A “dirty” or “clean” indicator may also be communicated on a hit to designate “clean-hit” or “dirty hit”.

If the access was a read operation and based on the cache hit, memory device 110 transmits, via DQ interface 112 and DQ interface 122, the corresponding cache line data (e.g., from data column circuitry group 132d and/or data EDC circuitry 143) to controller 120. If the access was a write operation, the controller transmits, potentially before the hit/miss indicator is transmitted by memory device 110, via DQ interface 112 and DQ interface 122, the corresponding cache line data to be written. Based on the cache hit, memory device 110 writes the received cache line data (e.g., to data column circuitry group 132d and/or data EDC circuitry 143) to memory array 130. If the write operation resulted in a “miss-clean”, memory device 110 may, based on a cache allocation policy (or mode) of memory device 110 and/or system 100, write the received cache line data to memory array 130, or ignore the data controller 120 transmitted (if any).

If the “valid” flag indicates the cache entry is not valid, any compare of the tag query value and stored tag value is also not valid (i.e., “miss-invalid”). Based on the miss invalid determination, memory device 110 transmits an “invalid” indicator to controller 120 via HM interface 113 and HM interface 123. If the access was a read operation, and based on the “invalid” indicator, controller 120 may later issue a command and provide data to replace (or “fill”), in memory array 130, the cache line entry corresponding to the tag query value that was directed to the invalid entry. If the access was a write operation, and based on the “miss invalid”, memory device 110 may, based on a cache allocation policy (or mode) of memory device 110 and/or system 100, write the received cache line data to memory array 130, or ignore the data controller 120 transmitted (if any).

If tag compare circuitry 142 finds the tag query value does not match the stored tag value in memory array 130 at the row and column addresses communicated by (or in association with) the cache read command, and the “valid” flag indicates the cache entry is valid, it is termed a cache “miss” and the cache line that cache control circuitry 125 is seeking to read from memory device 110 is not present in memory array 130. If the tag query value and stored tag value did not match (and are valid), and the “dirty” flag indicates the corresponding cache line data has not been altered, the miss is termed a “miss clean”. Based on the miss clean, memory device 110 transmits a “miss clean” indicator to controller 120 via HM interface 113 and HM interface 123.

If the access was a read operation, and based on the miss clean, memory device 110 may not transmit the corresponding cache line data to controller 120, may transmit an undefined response, or may transmit data associated with a different command (e.g., from a flush buffer). Controller 120 may, based on a cache allocation policy (or mode) of memory device 110 and/or system 100, later issue a command and provide data to replace (or “fill”), in memory array 130, the tag and flag information and cache line entry corresponding to the tag query value that resulted in a miss clean. If the access was a write operation, and based on the “miss clean”, memory device 110 may, based on a cache allocation policy (or mode) of memory device 110 and/or system 100, write the received cache line data to memory array 130, or ignore the data controller 120 transmitted (if any).

If, (1) the “valid” flag indicates the cache entry is valid, and (2) tag query value and stored tag value did not match and (3) the “dirty” flag indicates the corresponding cache line data has been altered, the miss is termed a “miss dirty”. Based on the miss dirty, memory device 110 transmits a “miss dirty” indicator to controller 120 via HM interface 113 and HM interface 123. If the access was a read operation, and based on the miss dirty, memory device 110 transmits, via DQ interface 112 and DQ interface 122, the corresponding altered (a.k.a., “dirty”) cache line data (e.g., from data column circuitry group 132d and/or data EDC circuitry 143) to controller 120. Further based on the miss dirty, memory device 110 may transmit the nonmatching stored tag value corresponding to the dirty cache line data to controller 120 via HM interface 113 and HM interface 123. Controller 120 may, based on a cache allocation policy (or mode), later issue a command and provide data to replace (or “fill”), in memory array 130, the tag and flag information and cache line entry corresponding to the tag query value that resulted in the miss dirty.

If the access was a write operation, and based on the “miss dirty”, controller 120 may, in some embodiments and/or instances, send the write data to memory device 110. In other embodiments and/or instances, controller 120 may not send the write data to memory device 110. If the access was a write operation, and based on the “miss dirty”, memory device 110 may, in some embodiments and/or instances, write received write data to memory array 130. In other embodiments and/or instances, memory device 110 may not write the received write data to memory array 130. In addition, based on the “miss dirty”, memory device 110 may, in some embodiments and/or instances, transmit the dirty data to controller 120 via DQ interface 112 in response the current access operation, may transmit the dirty data to controller 120 via DQ interface 112 in response to a future operation or command, may place the dirty data in a flush buffer, or may do nothing with the dirty data.

In an embodiment, tag and flags 130a may include “lock” bits. For example, a “locked” flag may be used to designate that the corresponding cache line entry should not be displaced from memory array 130. Thus, an access response may communicate a “locked” indicator via HM interface 113 along with hit, miss, etc. indicators. Controller 120 will then know that the access request, although it resulted in a miss, will not be placed in memory array 130 and thus should be written or read directly from the backing memory and/or additional levels of cache 150.

In an embodiment, memory device 110, and/or controller 120 may implement a cache allocation policy. The cache allocation policy may be implemented device/system-wide (e.g., via modes in controller 120 and/or memory device 110) or on a command-by-command basis (e.g., with a bit in a command field). If an access is “with allocation”, the cache line that missed is placed into memory array 130 replacing/displacing the corresponding cache line entry whether dirty, or clean, etc. that was at that location previously. If an access is “without allocation”, if the access results in a miss, the cache line that missed is not placed into memory array 130. Rather, controller 120 will need to read/write the cache line from/to backing store and/or additional cache levels 150.

In an embodiment, memory device 110, and/or controller 120 may implement a mode or access command field that allows modification of the “dirty” bit field of cache line entries. For example, a command or command field could indicate a “clear dirty bit” operation is to be performed with the command(s). Thus, when in the “clear dirty bit” mode, for a read operation that is a dirty hit, or that is a miss dirty without allocate, the dirty bit is cleared (i.e., indicates cache line is unmodified) in the corresponding cache line entry since memory controller 120 is committed to sending the data received from memory device 110 to backing store and/or additional cache levels 150. Similarly, when in the “clear dirty bit” mode, for a write operation that is a write hit or a write miss with allocate, the dirty bit is cleared (i.e., indicates cache line is unmodified) in the corresponding cache line entry since controller 120 is committing to sending the data transmitted to memory device 110 to backing store and/or additional cache levels 150.

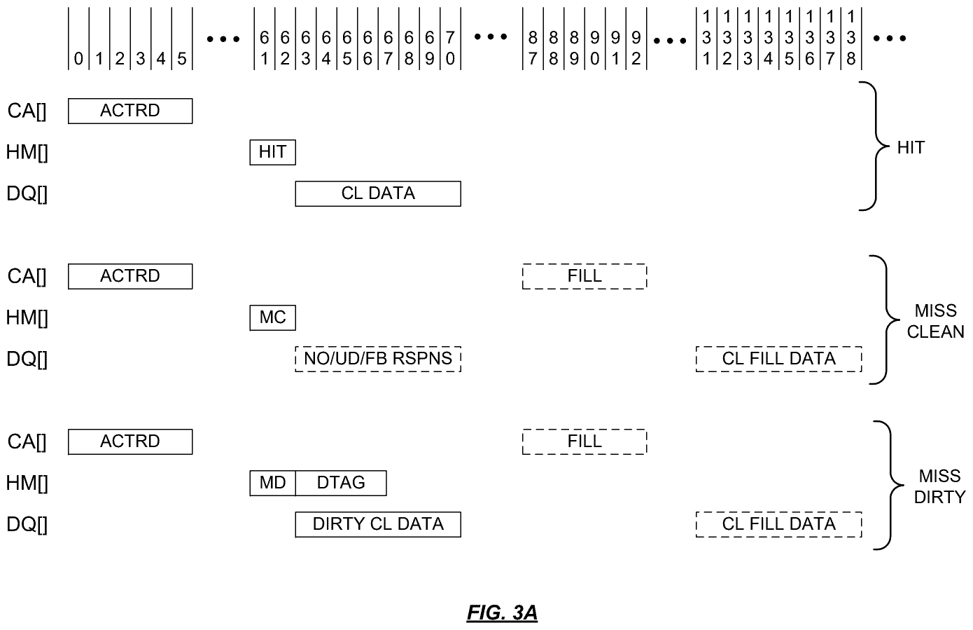

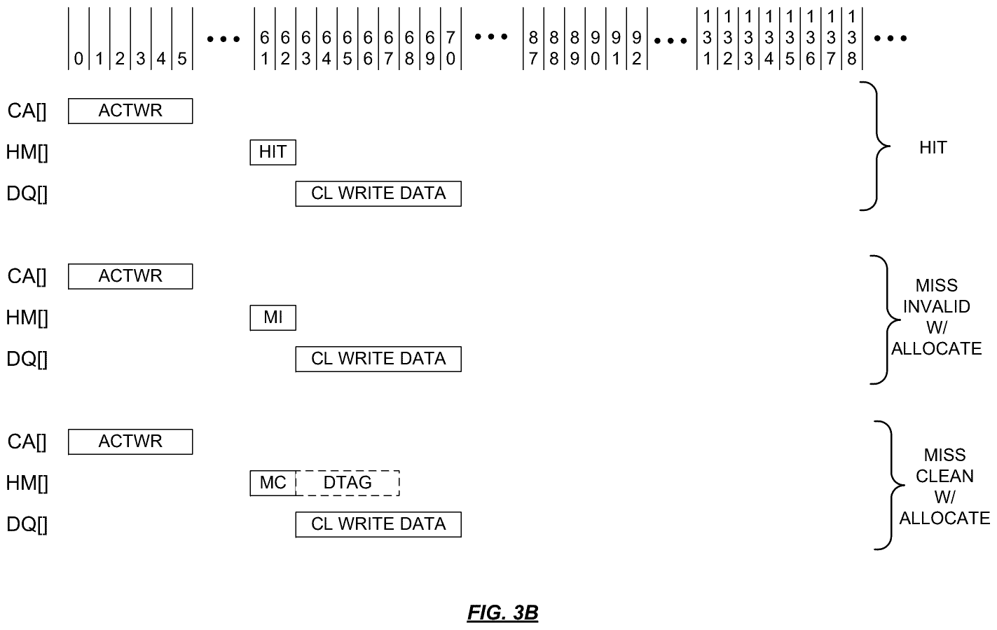

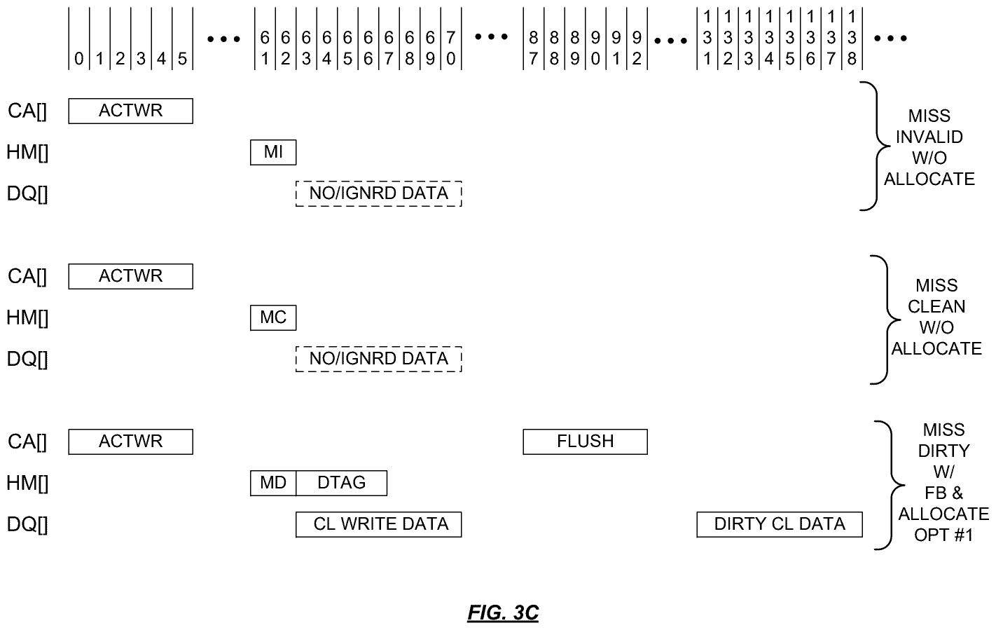

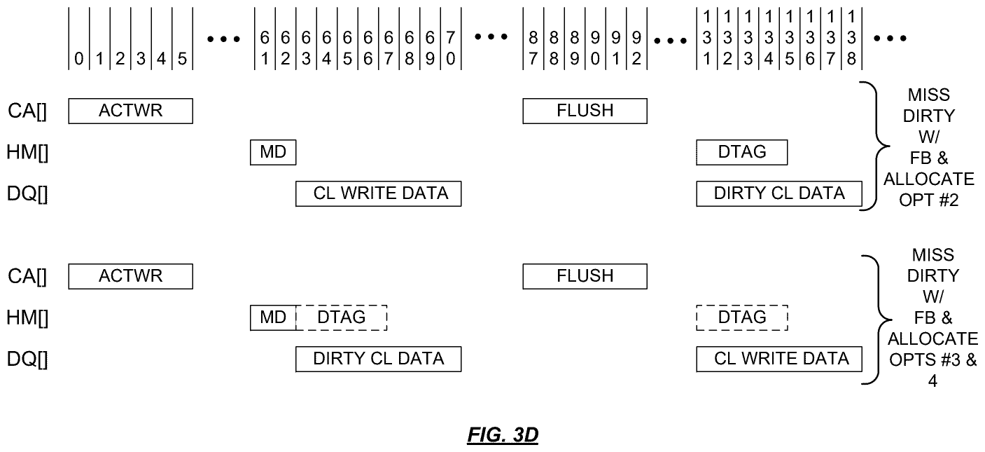

Thus, it should be understood from the foregoing that the content communicated via DQ interface 112 and DQ interface 122 varies based on whether memory device 110 (and tag compare circuitry 142, in particular) determined the tag query value corresponds to a hit clean, hit dirty, miss invalid, miss clean, miss dirty, etc. Likewise, it should be understood that the content communicated via HM interface 113 and HM interface 123 varies (e.g., does or does not communicate the “dirty” tag) based on whether memory device 110 (and tag compare circuitry 142, in particular) determined the tag query value corresponds to a hit clean, hit dirty, miss invalid, miss clean, or miss dirty, etc. This is further illustrated in FIGS. 3A-3D where the DQ[ ] and HM[ ] busses communicate different data, for both read operations and write operations, depending upon the tag compare and flag results.

In an embodiment, the EDC scheme implemented by tag EDC circuitry 141 and the EDC scheme implemented by data EDC circuitry 143 may be different. In addition, having separate tag EDC circuitry 141 and data EDC circuitry 143 may allow the EDC checking and/or correcting for the cache tags and cache flags to be faster than that of checking and/or correcting of the cache line data. This may allow the hit/miss and clean/dirty results to be determined faster than waiting for the EDC checking/correcting of the (larger) cache line data to finish before comparing tag values.

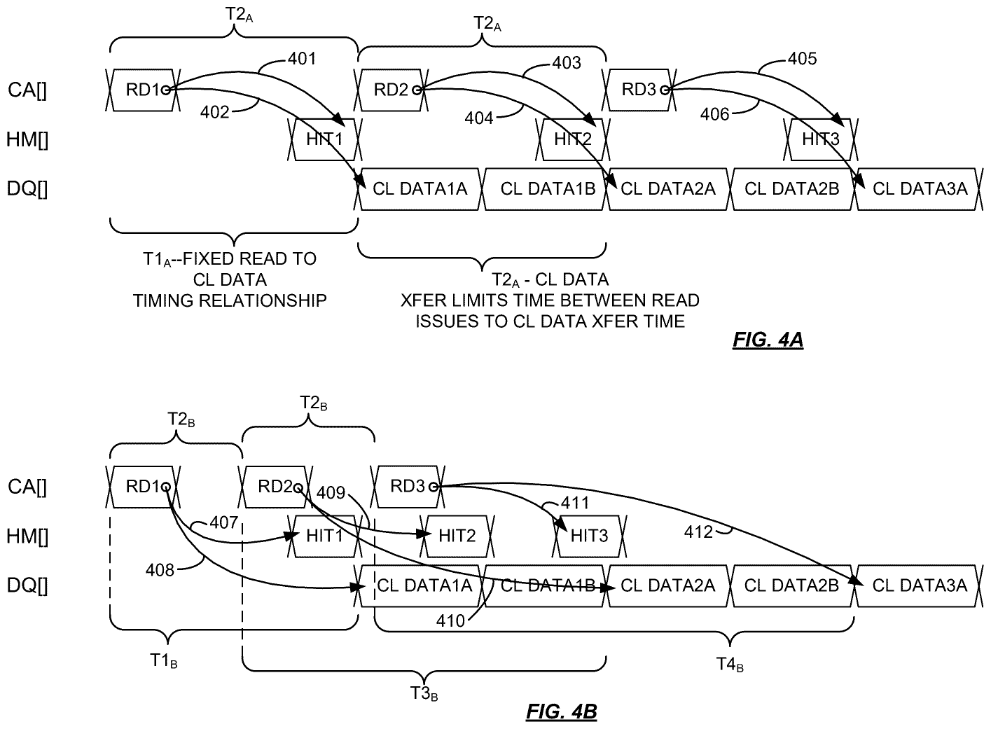

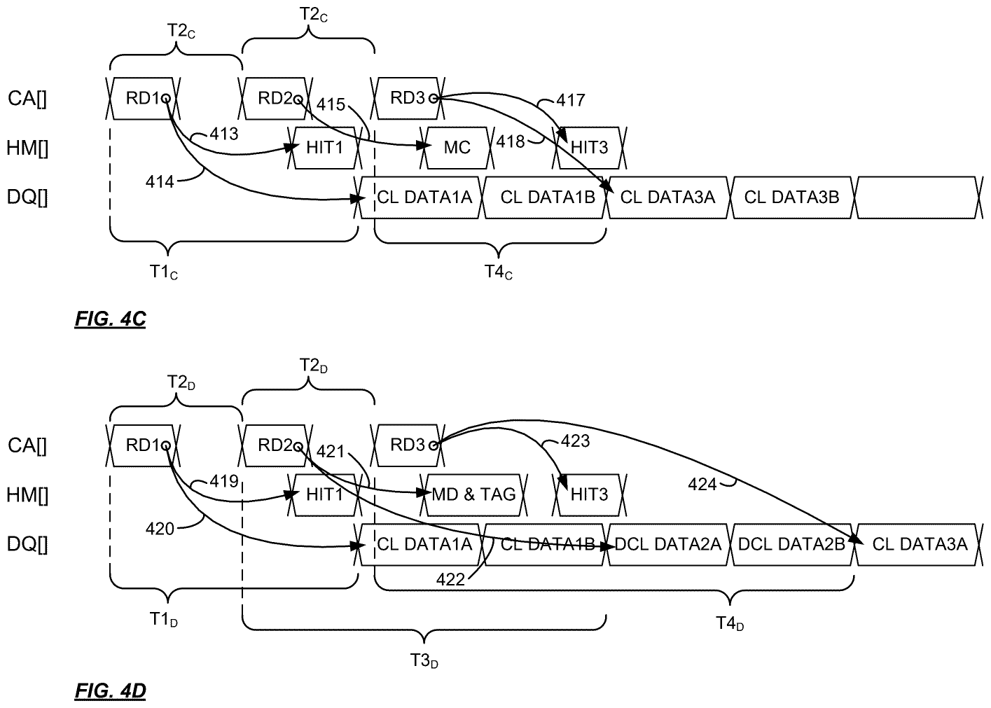

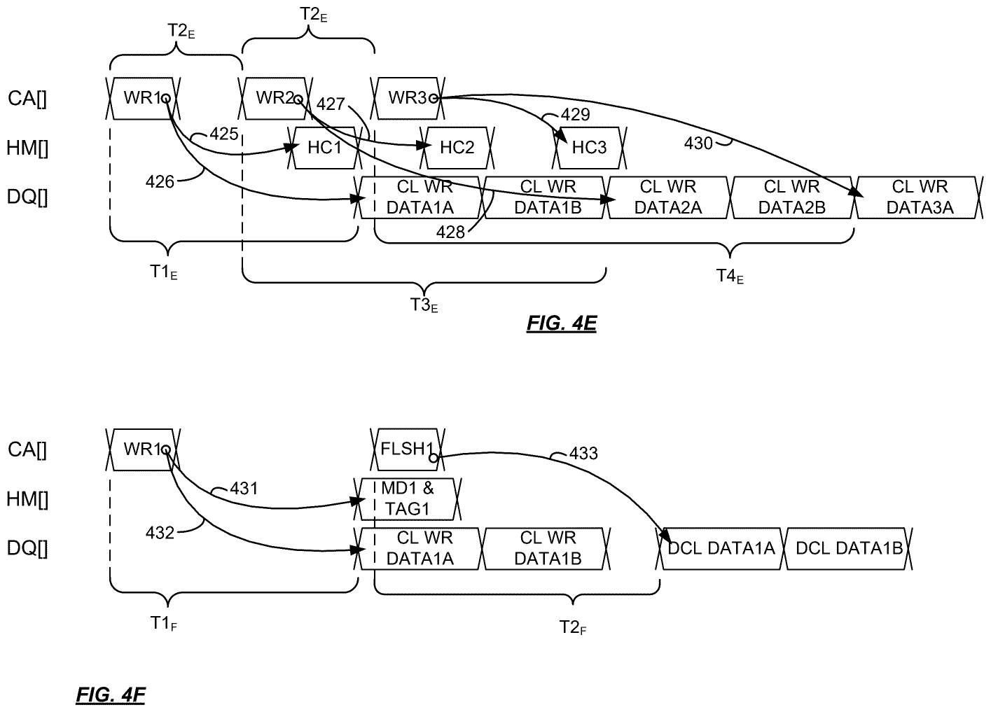

FIGS. 4A-4D illustrate example timing relationships. FIG. 4A illustrates a fixed timing relationship between a read (or ACTRD) command on a command/address bus, the tag compare results on the HM bus, and the cache line data. In FIG. 4A, a first read command (RD1), a second read command (RD2) and a third read command (RD3) are illustrated as being transmitted (e.g., by controller 120) via a CA bus, respectively, each a minimum allowed time (T2_{A}) after the preceding read command. In response to RD1, a hit indicator (HIT1) is transmitted (e.g., by memory device 110) a fixed time after RD1. This is illustrated in FIG. 4A by arrow 401 running from RD1 to HIT1. Similarly, based on RD1 and determining RD1 corresponds to a cache hit, cache line data (CL DATA1A and CL DATA1B) is transmitted on the DQ bus a fixed time (T1_{A}) after RD1 (and/or HIT1). This is illustrated in FIG. 4A by arrow 402 running from RD1 to CL DATA1A.

A minimum allowed time (T2_{A}) after RD1, a second read command (RD2) is transmitted on the CA bus. In response to RD2, a hit indicator (HIT2) is transmitted (e.g., by memory device 110) a fixed time after RD2. This is illustrated in FIG. 4A by arrow 403 running from RD2 to HIT2. Similarly, based on RD2 and determining RD2 corresponds to a cache hit, cache line data (CL DATA2A and CL DATA2B) is transmitted on the DQ bus a fixed time after RD2 (and/or HIT2). This is illustrated in FIG. 4A by arrow 404 running from RD2 to CL DATA2A. Note that the minimum allowed time (T2_{A}) between RD1 and RD2 is limited to a minimum determined by the amount of time it takes to transfer a cache line of data (e.g., CL DATA1A and CL DATAIB).

A minimum allowed time (T2_{A}) after RD2, a third read command (RD3) is transmitted on the CA bus. In response to RD3, a hit indicator (HIT3) is transmitted (e.g., by memory device 110) a fixed time after RD3. This is illustrated in FIG. 4A by arrow 405 running from RD3 to HIT3. Similarly, based on RD3 and determining RD3 corresponds to a cache hit, cache line data (CL DATA3A etc.) is transmitted on the DQ bus a fixed time after RD3 (and/or HIT3). This is illustrated in FIG. 4A by arrow 406 running from RD3 to CL DATA1A. Note that the minimum allowed time (T2_{A}) between RD2 and RD3 is limited to a minimum determined by the amount of time it takes to transfer a cache line of data (e.g., CL DATA2A and CL DATA2B).

FIG. 4B illustrates a fixed timing relationship between a read (or ACTRD) command on a command/address bus and the tag compare results on the HM bus but a variable relationship between the read command and the cache line data. In FIG. 4B, a first read command (RD1), a second read command (RD2) and a third read command (RD3) are illustrated as being transmitted (e.g., by controller 120) via a CA bus, respectively, each a minimum allowed time (T2_{B}) after the preceding read command. In response to RD1, a hit indicator (HIT1) is transmitted (e.g., by memory device 110) a fixed time after RD1. This is illustrated in FIG. 4B by arrow 407 running from RD1 to HIT1. Similarly, based on RD1 and determining RD1 corresponds to a cache hit, cache line data (CL DATA1A and CL DATA1B) is transmitted on the DQ bus a first amount of time (T1_{B}) after RD1 (and/or HIT1). This is illustrated in FIG. 4B by arrow 408 running from RD1 to CL DATA1A.

A minimum allowed time (T2_{B}) after RD1, a second read command (RD2) is transmitted on the CA bus. In response to RD2, a hit indicator (HIT2) is transmitted (e.g., by memory device 110) a fixed time after RD2. This is illustrated in FIG. 4B by arrow 409 running from RD2 to HIT2. Similarly, based on RD2 and determining RD2 corresponds to a cache hit, cache line data (CL DATA2A and CL DATA2B) is transmitted on the DQ bus a second amount of time (T3_{B}) after RD2 (and/or HIT2). This is illustrated in FIG. 4B by arrow 410 running from RD2 to CL DATA2A. Note that the second amount of time (T3_{B}) from RD2 to the start of C L DATA2A is limited to a minimum determined by the amount of time it takes to complete the transfer of the cache line of data from the previous read command, RD1 (i.e., CL DATA1A and CL DATAIB).

A minimum allowed time (T2_{B}) after RD2, a third read command (RD3) is transmitted on the CA bus. In response to RD3, a hit indicator (HIT3) is transmitted (e.g., by memory device 110) a fixed time after RD3. This is illustrated in FIG. 4B by arrow 411 running from RD3 to HIT3. Similarly, based on RD3 and determining RD3 corresponds to a cache hit, cache line data (CL DATA3A etc.) is transmitted on the DQ bus a third amount of time (T4_{B}) after RD3 (and/or HIT3). This is illustrated in FIG. 4B by arrow 412 running from RD3 to CL DATA3A. Note that the third amount of time (T4_{B}) from RD3 to the start of C L DATA3A is limited to a minimum determined by the amount of time it takes to complete the transfer of the cache line of data from the previous two read commands, RD1 and RD2 (i.e., CL DATA1A, CL DATA1B, CL DATA2A, and CL DATA2B). It should be understood that since the amount of time to transfer a cache line of data (e.g., T2_{A}) on the DQ bus is greater than the minimum allowed time between read command (e.g., T2_{B}), T4_{B}≠T3_{B}≠T1_{B} and T4_{B}>T3_{B}>T1_{B}.

FIG. 4C illustrates a fixed timing relationship between a read (or ACTRD) command on a command/address bus and the tag compare results on the HM bus, variable content on the data bus, and a variable timing relationship between the read command and the cache line data. In FIG. 4C, a first read command (RD1), a second read command (RD2) and a third read command (RD3) are illustrated as being transmitted (e.g., by controller 120) via a CA bus, respectively, each a minimum allowed time (T2_{C}) after the preceding read command. In response to RD1, a hit indicator (HIT1) is transmitted (e.g., by memory device 110) a fixed time after RD1. This is illustrated in FIG. 4C by arrow 413 running from RD1 to HIT1. Similarly, based on RD1 and determining RD1 corresponds to a cache hit, cache line data (CL DATA1A and CL DATA1B) is transmitted on the DQ bus a first amount of time (T1_{C}) after RD1 (and/or HIT1). This is illustrated in FIG. 4C by arrow 414 running from RD1 to CL DATA1A.

A minimum allowed time (T2_{C}) after RD1, a second read command (RD2) is transmitted on the CA bus. In response to RD2, a miss clean indicator (MC) is transmitted (e.g., by memory device 110) a fixed time after RD2. This is illustrated in FIG. 4C by arrow 415 running from RD2 to HIT2. Based on RD2 and determining RD2 corresponds to a miss clean, no data is transmitted on the DQ bus based on RD2 (and/or MC). Note that because no data was transmitted on the DQ bus in response to RD2, the DQ bus becomes available sooner to transmit data for a subsequent command to RD2 (i.e., CL DATA3A etc.).

A minimum allowed time (T2_{C}) after RD2, a third read command (RD3) is transmitted on the CA bus. In response to RD3, a hit indicator (HIT3) is transmitted (e.g., by memory device 110) a fixed time after RD3. This is illustrated in FIG. 4C by arrow 417 running from RD3 to HIT3. Similarly, based on RD3 and determining RD3 corresponds to a cache hit, cache line data (CL DATA3A etc.) is transmitted on the DQ bus a second amount of time (T4_{C}) after RD3 (and/or HIT3). This is illustrated in FIG. 4C by arrow 418 running from RD3 to CL DATA3A. Note that the second amount of time (T4_{C}) from RD3 to the start of CL DATA3A is shorter than the amount of time it would have taken to complete the transfer of the cache line of data from the previous two read commands if both RD1 and RD2 had hit. Also note that since RD2 was a miss, T4_{B} in FIG. 4B would be greater than T4_{C} in FIG. 4C.

FIG. 4D illustrates a fixed timing relationship between a read (or ACTRD) command on a command/address bus and the tag compare results on the HM bus, variable content on the hit/miss bus, variable content on the data bus, and a variable timing relationship between the read command and the cache line data. In FIG. 4D, a first read command (RD1), a second read command (RD2) and a third read command (RD3) are illustrated as being transmitted (e.g., by controller 120) via a CA bus, respectively, each a minimum allowed time (T2_{D}) after the preceding read command. In response to RD1, a hit indicator (HIT1) is transmitted (e.g., by memory device 110) a fixed time after RD1. This is illustrated in FIG. 4D by arrow 419 running from RD1 to HIT1. Similarly, based on RD1 and determining RD1 corresponds to a cache hit, cache line data (CL DATA1A and CL DATAIB) is transmitted on the DQ bus a first amount of time (T1_{D}) after RD1 (and/or HIT1). This is illustrated in FIG. 4D by arrow 420 running from RD1 to CL DATA1A.

A minimum allowed time (T2_{D}) after RD1, a second read command (RD2) is transmitted on the CA bus. In response to RD2, a miss dirty indicator (MD) and the stored tag value associated with the miss dirty are transmitted (e.g., by memory device 110) a fixed time after RD2. This is illustrated in FIG. 4D by arrow 421 running from RD2 to “MD and tag” on the HM bus. Similarly, based on RD2 and determining RD2 corresponds to a miss dirty, the dirty cache line data (DCL DATA2A and DCL DATA2B) is transmitted (e.g., by memory device 110) on the DQ bus a second amount of time (T3_{D}) after RD2. This is illustrated in FIG. 4D by arrow 422 running from RD2 to DCL DATA2A. Note that the second amount of time (T3_{D}) from RD2 to the start of DCL DATA2A is limited to a minimum determined by the amount of time it takes to complete the transfer of the cache line of data from the previous read command, RD1 (i.e., CL DATA1A and CL DATAIB) and may also include, in some embodiments, additional time to “turn around” the DQ bus from being driven by the controller (e.g., controller 120) to being driven by the memory device (e.g., memory device 110).

In an embodiment, memory device 110, controller 120, and/or system 100 may have modes whereby rather than DCL DATA2A and DCL DATA2B being transmitted, DCL DATA2A and DCL DATA2B via DQ bus after T3_{D}, DCL DATA2A and DCL DATA2B are transmitted to a flush buffer and other data from the flush buffer (e.g., other dirty cache line data) is transmitted after T3_{D} in the time shown in FIG. 4D as being allotted to DCL DATA2A and DCL DATA2B.

A minimum allowed time (T2_{D}) after RD2, a third read command (RD3) is transmitted on the CA bus. In response to RD3, a hit indicator (HIT3) is transmitted (e.g., by memory device 110) a fixed time after RD3. This is illustrated in FIG. 4D by arrow 423 running from RD3 to HIT3. Similarly, based on RD3 and determining RD3 corresponds to a cache hit, cache line data (CL DATA3A etc.) is transmitted on the DQ bus a third amount of time (T4_{D}) after RD3 (and/or HIT3). This is illustrated in FIG. 4D by arrow 424 running from RD3 to CL DATA3A.

FIG. 4E illustrates a fixed timing relationship between a write (or ACTWR) command on a command/address bus and the tag compare results on the HM bus, variable content on the data bus, and a variable timing relationship between the write command and the cache line data. In FIG. 4E, a first write command (WR1), a second write command (WR2) and a third write command (WR3) are illustrated as being transmitted (e.g., by controller 120) via a CA bus, respectively, each a minimum allowed time (T2_{E}) after the preceding write command. In response to WR1, a hit clean indicator (HC1) is transmitted (e.g., by memory device 110) a fixed time after WR1. This is illustrated in FIG. 4E by arrow 425 running from WR1 to HC1. Similarly, based on WR1 cache line write data (CL WR DATA1A and CL WR DATA1B) is transmitted on the DQ bus by the controller (e.g., controller 120) a first amount of time (T1_{E}) after WR1 (and/or HC1). This is illustrated in FIG. 4E by arrow 426 running from WR1 to CL WR DATA1A.

A minimum allowed time (T2_{E}) after WR1, a second write command (WR2) is transmitted on the CA bus. In response to WR2, a hit clean indicator (HC2) is transmitted (e.g., by memory device 110) a fixed time after WR2. This is illustrated in FIG. 4E by arrow 427 running from WR2 to HC2. Similarly, based on WR2 cache line write data (CL WR DATA2A and CL WR DATA2B) is transmitted on the DQ bus by the controller (e.g., controller 120) a second amount of time (T3_{E}) after WR2 (and/or HC2). This is illustrated in FIG. 4E by arrow 428 running from WR2 to CL WR DATA2A.

A minimum allowed time (T2_{E}) after WR2, a third write command (WR3) is transmitted on the CA bus. In response to WR3, a hit clean indicator (HC3) is transmitted (e.g., by memory device 110) a fixed time after WR3. This is illustrated in FIG. 4E by arrow 429 running from WR3 to HC3. Similarly, based on WR3 cache line write data (CL WR DATA3A and CL WR DATA3B) is transmitted on the DQ bus by the controller (e.g., controller 120) a third amount of time (T4_{E}) after WR3 (and/or HC3). This is illustrated in FIG. 4E by arrow 430 running from WR3 to CL WR DATA3A. Note that the third amount of time (T4_{E}) from WR3 to the start of CL WR DATA3A is limited to a minimum determined by the amount of time it takes to complete the transfer of the cache line of data from the previous two write commands, WR1 and WR2 (i.e., CL WR DATA1A, CL WR DATA1B, CL WR DATA2A, and CL WR DATA2B). It should be understood that since the amount of time to transfer a cache line of data on the DQ bus is greater than the minimum allowed time between write commands (e.g., T2_{E}), T4_{E}≠T3_{E}≠T1_{E} and T4_{E}>T3_{E}>T1_{E}.

FIG. 4F illustrates a fixed timing relationship between a write (or ACTWR) command on a command/address bus and the tag compare results on the HM bus, and a variable timing relationship between the write command and the dirty cache line data. In FIG. 4F, a first write command (WR1) is illustrated as being transmitted (e.g., by controller 120) via a CA bus. In response to WR1, a miss dirty indicator (MD1) and tag value (TAG2) is transmitted (e.g., by memory device 110) a fixed time after WR1. This is illustrated in FIG. 4F by arrow 431 running from WR1 to MD1 and TAG1. Similarly, based on WR1 cache line write data (CL WR DATA1A and CL WR DATA1B) is transmitted on the DQ bus by the controller (e.g., controller 120) a first amount of time (T1_{F}) after WR1 (and/or MD1). This is illustrated in FIG. 4F by arrow 432 running from WR1 to CL WR DATA1A. A variable amount of time later, a flush command (FLSH1) is illustrated as being transmitted (e.g., by controller 120) via a CA bus. In response to FLSH1, dirty cache line data (DCL DATA1A and DCL DATA1B) is transmitted on the DQ bus by the memory device (e.g., memory device 110 120) a second amount of time (T2_{F}) after FLSH1 (and/or WR1 and/or MD1). This is illustrated in FIG. 4F by arrow 433 running from FLSH1 to DCL DATA1A.

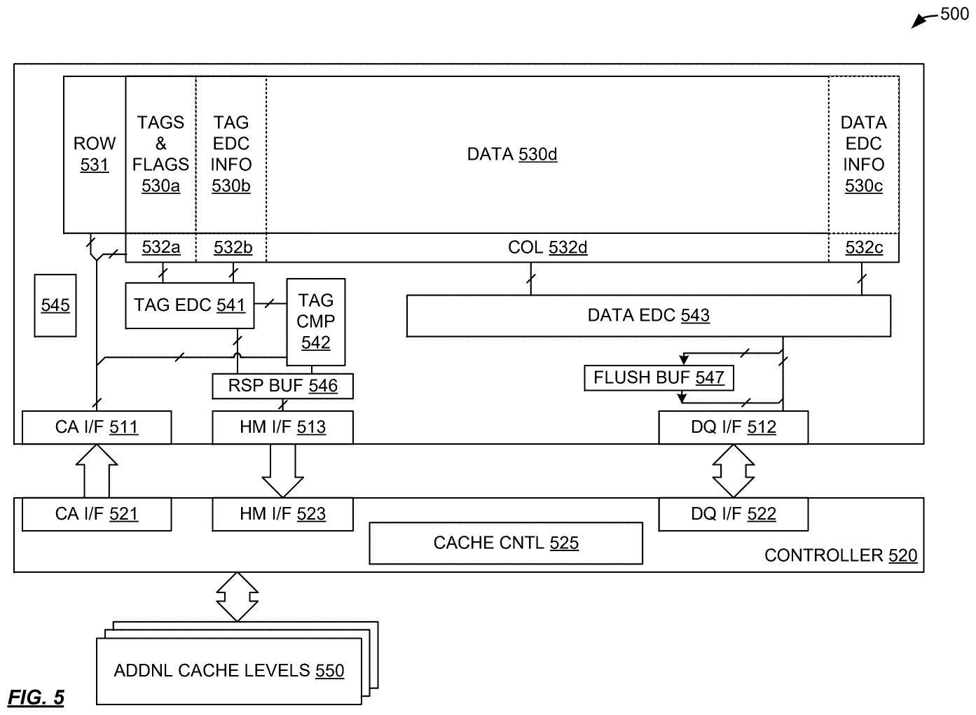

FIG. 5 is a block diagram illustrating a memory system. In FIG. 5, memory system 500 comprises memory device 510 and memory controller 520. Memory device 510 includes command/address (CA) interface 511, data (DQ) interface 512, hit/miss (HM) interface 513, memory array 530, row circuitry 531, column circuitry 532, tag error detection and correction (EDC) circuitry 541, tag compare circuitry 542, data EDC circuitry 543, control circuitry 545, response buffer 546, and flush buffer 547. Memory controller 520 includes CA interface 521, DQ interface 522, hit/miss (HM) interface 523, and cache control circuitry 525. Controller 520 is operatively coupled to additional cache levels 550, main memory (not shown in FIG. 5), and/or backing store (not shown in FIG. 5).

CA interface 521 of controller 520 is operatively coupled to CA interface 511 of memory device 510. CA interface 521 of controller 520 is operatively coupled to CA interface 511 of memory device 510 to at least communicate, from controller 520, commands, addresses, and cache tag query values to memory device 510. DQ interface 522 of controller 520 is operatively coupled to DQ interface 512 of memory device 510. DQ interface 522 of controller 520 is operatively coupled to DQ interface 512 of memory device 510 to communicate data (e.g., cache lines, dirty cache lines, cache line fill data) between controller 520 and memory device 510. HM interface 523 of controller 520 is operatively coupled to HM interface 513 memory device 510. HM interface 523 of controller 520 is operatively coupled to HM interface 513 memory device 510 to at least communicate, from memory device 510, indicators of a cache tag compare result (i.e., hit or miss), and whether a cache miss was to a clean or dirty cache line (e.g., cache flag indicators) to controller 520.

Memory controller 520 and memory device 510 may be integrated circuit type devices, such as are commonly referred to as “chips”. A memory controller, such as memory controller 520, manages the flow of data going to and from memory devices and/or memory modules. Memory device 510 may be a standalone device, or may be a component of a memory module such as a DIMM module used in servers. Memory device 510 may be, or be part of, a component having a “stack” of memory devices. Memory device 510 may be a device that adheres to, or is compatible with, a dynamic random access memory (DRAM) specification. A memory controller can be a separate, standalone chip, or integrated into another chip. For example, a memory controller 520 may be included on a single die with a microprocessor, included as a chip co-packaged with one or more microprocessor chips, included as part of a more complex integrated circuit system such as a block of a system on a chip (SOC), or be remotely coupled to one or more microprocessors via a fabric interconnect or other type of interconnect.

CA interface 511 of memory device 510 is operatively coupled to row circuitry 531, column circuitry 532, and tag compare circuitry 542. CA interface 511 is operatively coupled to row circuitry 531 to at least activate rows in memory array 530. CA interface 511 is operatively coupled to column circuitry 532 to at least sense values from activated rows, and to decode and provide the values of selected columns to other circuitry of memory device 510 (e.g., data EDC circuitry 543, tag EDC circuitry 541, response buffer 546, flush buffer 547, DQ interface 512, etc.) CA interface 511 is operatively coupled to column circuitry 532 to at least provide tag compare circuitry 542 with tag query values indicated by commands.

Memory array 530 of memory device 510 is logically subdivided into column groups 530a-530d. Column group 530a is to store cache tags and cache flags. Column group 530b is to store tag EDC information. Column group 530c is to store cache line data (a.k.a., cache line) EDC information. Column group 530d is to store cache lines.

Column circuitry 532 is subdivided into column circuitry groups 532a-132d that may have different decoding functions. Column circuitry group 532a is to decode a column address and provide the addressed cache tags and cache flags to tag EDC circuitry 541. Likewise, tag EDC information column circuitry group 532b is to decode the column address and provide the addressed cache tags and cache flags to tag EDC circuitry 541. Column circuitry group 532c is to is to decode the column address and provide the addressed cache line EDC information to data EDC circuitry 543. Column circuitry group 532d is to decode the column address and provide the addressed cache line to data EDC circuitry 543.

Tag EDC circuitry 541 is operatively coupled to column circuitry group 532a, tag EDC information column circuitry group 532b, and response buffer 546. Tag EDC circuitry 541 is operatively coupled to column circuitry group 532a to receive, from cache tags and flags column group 530a and via cache tags and flags column circuitry group 532a, stored cache tag and cache flag values addressed by a command. Tag EDC circuitry 541 is operatively coupled to tag EDC information column circuitry group 532b to receive, from tag EDC information group 530b and via tag EDC information column circuitry group 532b, stored cache tag EDC information addressed by the command. Tag EDC circuitry 541 may use the received cache tag EDC information to check and/or correct corresponding cache tag and flag values that were accessed in response to the command. Tag EDC circuitry 541 may provide the checked and/or corrected cache tag and flag values to tag compare circuitry 542 and response buffer 546. Response buffer is operatively coupled to HM interface 513. Response buffer 546 is operatively coupled to HM interface 513 to manage the timing of hit/miss/tag responses transmitted to controller 520. In other words, response buffer 546 may allow commands (e.g., ACTRD, ACTWR) to be issued with flexible timing (e.g., variable or less than the amount of time to communicate hit/miss results via the HM bus) and/or the hit/miss/tag results be returned using flexible timing.

Data EDC circuitry 543 is operatively coupled to data EDC information column circuitry group 532c, data column circuitry group 532d, and DQ interface 512. Data EDC circuitry 543 is operatively coupled to data EDC information column circuitry group 532c to receive, from data EDC column group 530c and via data EDC information column circuitry group 532c, stored data EDC information addressed by the command. Data EDC circuitry 543 is operatively coupled to data column circuitry group 532d to receive, from cache line data column group 530d and via cache line data column circuitry group 532d, stored cache line data addressed by the command. Data EDC circuitry 543 may use the received data EDC information to check and/or correct corresponding cache line data that was accessed in response to the command. Data EDC circuitry 543 may provide the checked and/or corrected cache line data to DQ interface 512 and/or flush buffer 547.

In an embodiment, the EDC scheme implemented by tag EDC circuitry 541 and the EDC scheme implemented by data EDC circuitry 543 may be different. In addition, having separate tag EDC circuitry 541 and data EDC circuitry 543 may allow the EDC checking and/or correcting for the cache tags and cache flags to be faster than that of checking and/or correcting of the cache line data. This may allow the hit/miss and clean/dirty results to be determined faster than waiting for the EDC checking/correcting of the (larger) cache line data to finish before comparing tag values.

Flush buffer 547 is operatively coupled to DQ interface 512. Flush buffer 547 is operatively coupled to data EDC 543 to receive dirty cache line data from memory array 130. Flush buffer 547 is operatively coupled to DQ interface 512 to transmit dirty cache line data. Flush buffer 547 may hold dirty cache line data for a period of time rather than driving the dirty cache line data a short time after the access (e.g., ACTRD) or write (e.g., ACTWR) command that triggered the dirty miss. Flush buffer 547 may also manage DQ bus turnarounds to minimize the impact of these bus turnarounds. Flush buffer 547 may manage dirty cache lines and DQ bus turnarounds in a manner similar to traditional write buffers. In an embodiment, controller 520 may use a command to read dirty cache line data from flush buffer 547. In an embodiment, controller 520 and memory device 510 may have a common set of rules (e.g., state machine) to transmit data from flush buffer 547 to controller 520. For example, data from flush buffer 547 may be transmitted in the data bus slot that would have been used by a read command was not used because the command resulted in a miss clean. In another example, data from flush buffer 547 may be transmitted during refresh operations performed by memory device 510.

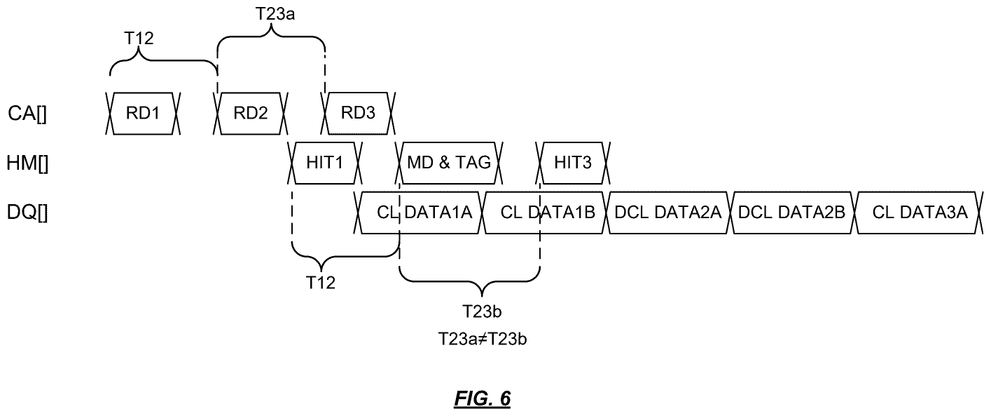

FIG. 6 is a timing diagram illustrating an example variable relationship between read commands and tag compare results. In FIG. 6, a first read command (RD1), a second read command (RD2) and a third read command (RD3) are illustrated as being transmitted (e.g., by controller 120) via a CA bus. RD2 is transmitted a first amount of time (T12) after the first read command. RD3 is transmitted a second amount of time T23a after the first read command. In an embodiment, T12=T23a. In another embodiment, T12≠T23a.

In response to RD1, a hit indicator (HIT1) is transmitted (e.g., by memory device 110) after RD1 is received. A first amount of time (T12) after RD1, a second read command (RD2) is transmitted on the CA bus. In response to RD2, a miss dirty indicator (MD) and the stored tag value associated with the miss dirty are transmitted (e.g., by memory device 110) on the HM bus the first amount of time (T12) after HIT1. A second amount of time (T23a) after RD2, a third read command (RD3) is transmitted on the CA bus. In response to RD3, a hit indicator (HIT3) is transmitted on the HM bus a third amount of time (T23b) after the miss dirty indicator (MD) and the stored tag value associated with RD2 were transmitted, where the time between receiving RD2 and RD3 is different than the time between the dirty miss being transmitted in response to RD2 and the hit being transmitted in response to RD3. In other words, T23a≠T23b.

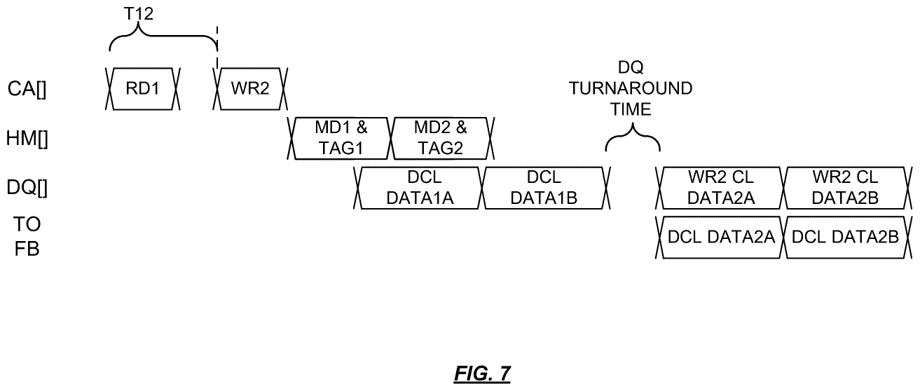

FIG. 7 is a timing diagram illustrating an example flush buffer function. In FIG. 7, a read command (RD1) and a write command (WR2) are illustrated as being transmitted (e.g., by controller 120) via a CA bus. WR2 is transmitted a first amount of time (T12) after the first read command, RD1. In response to RD1, a miss dirty indicator (MD) and the stored tag value associated with the RD1 miss dirty are transmitted (e.g., by memory device 110) on the HM bus. In response to WR2, a miss dirty indicator (MD) and the stored tag value associated with the WR2 miss dirty are transmitted (e.g., by memory device 110) on the HM bus. Also based on RD1 and determining RD1 corresponds to a miss dirty, the dirty cache line data (DCL DATA1A and DCL DATA1B) is transmitted (e.g., by memory device 110) on the DQ bus. Based on WR2 being a write, a DQ “turnaround” time is inserted to allow transmission to shift from the memory device to the controller so that the controller may transmit the write data associated with WR2. The data associated with WR2 is then transmitted on the DQ bus by the controller. However, since the memory device is no longer transmitting on the DQ bus, it inserts the dirty cache line data associated with WR2's dirty miss in a flush buffer (e.g., flush buffer 547) to be transmitted after the memory device regains the ability to transmit on the DQ bus.

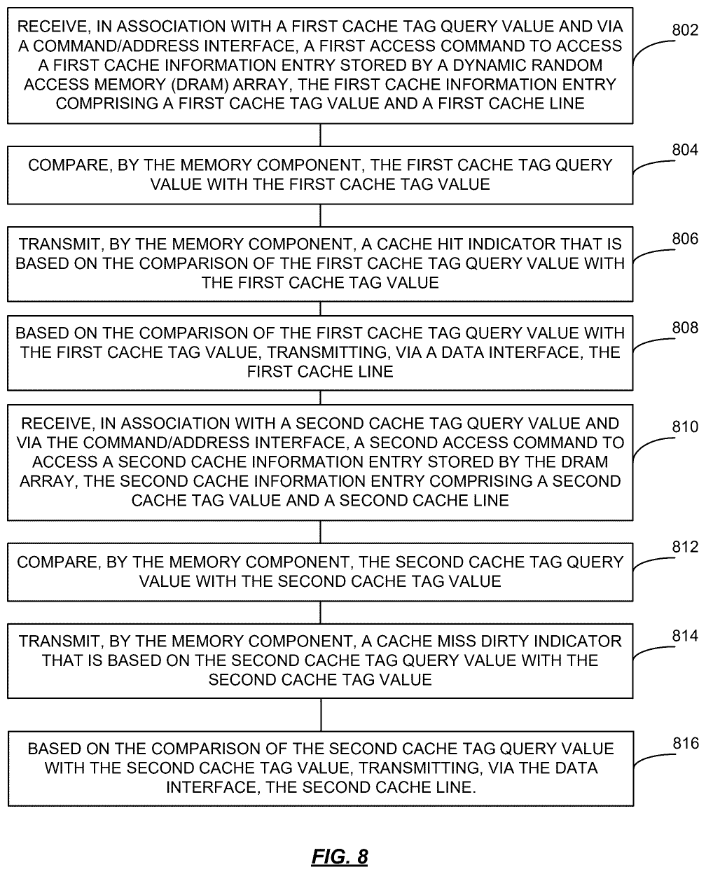

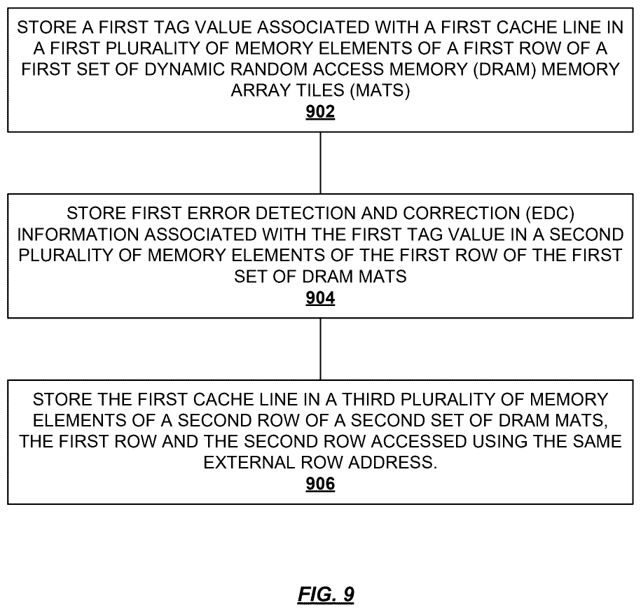

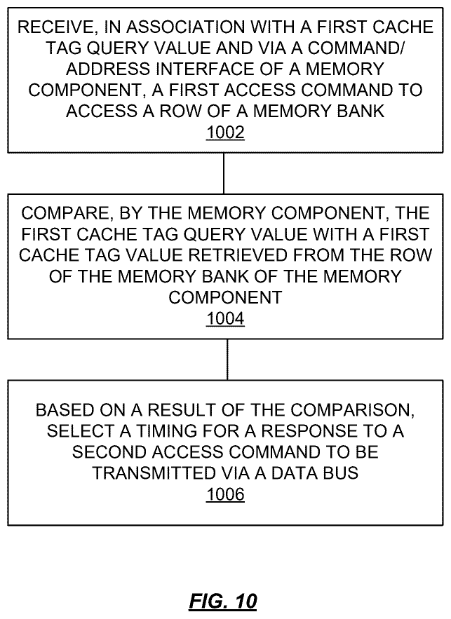

FIG. 8 is a flowchart illustrating a method of operating a memory component. One or more steps illustrated in FIG. 8 may be performed by, for example, memory system 100, memory system 500, and/or their components. In association with a first cache tag query value and via a command/address interface, a first access command to access a first cache information entry stored by a dynamic random access memory (DRAM) array is received where the first cache information entry comprises a first cache tag value and a first cache line (802). For example, memory device 110 may receive, from controller 120, a first combined row and column command (e.g., ACTRD) to activate a first addressed row, read the first set of addressed data columns, that comprise at least a first cache tag value and a first cache line, from the activated row, and compare a first tag value retrieved from memory array 130 (and tag and flags column group 130a, in particular) to a first tag query value specified by the first command.

By the memory component, the first cache tag query value is compared with the first cache tag value (804). For example, tag compare circuitry 142 of memory device 110 may compare the first tag value retrieved from memory array 130 at the addressed row and columns with the first tag query value specified by the first command. By the memory component, a cache hit indicator that is based on the comparison of the first cache tag query value with the first cache tag value is transmitted (806). For example, HM interface 113 of memory device 110 may transmit, to controller 120 and based on the comparison of the first tag value retrieved from memory array 130 and the first tag query value specified by the first command, a cache hit indicator. Based on the comparison of the first cache tag query value with the first cache tag value and via a data interface, the first cache line is transmitted (808). For example, based on the comparison of the first tag value retrieved from memory array 130 and the first tag query value specified by the first command, DQ interface 112 may transmit, to controller 120, the first cache line data retrieved from memory array 130 (and data column group 130d, in particular).

In association with a second cache tag query value and via a command/address interface, a second access command to access a second cache information entry stored by a dynamic random access memory (DRAM) array is received where the second cache information entry comprises a second cache tag value and a second cache line (810). For example, memory device 110 may receive, from controller 120, a second combined row and column command to activate a second addressed row, read the second set of addressed data columns, that comprise at least a second cache tag value and a second cache line, from the activated row, and compare a second tag value retrieved from memory array 130 (and tags and flags column group 130a, in particular) to a second tag query value specified by the second command.

By the memory component, the second cache tag query value is compared with the second cache tag value (812). For example, tag compare circuitry 142 of memory device 110 may compare the second tag value retrieved from memory array 130 at the addressed row and columns with the second tag query value specified by the second command. By the memory component, a cache hit indicator that is based on the comparison of the second cache tag query value with the second cache tag value is transmitted (814). For example, HM interface 113 of memory device 110 may transmit, to controller 120 and based on the comparison of the second tag value retrieved from memory array 130 and the second tag query value specified by the second command, a cache miss dirty indicator. Based on the comparison of the second cache tag query value with the second cache tag value and via a data interface, the second cache line is transmitted (816). For example, based on the comparison of the second tag value retrieved from memory array 130 and the second tag query value specified by the second command, DQ interface 112 may transmit, to controller 120, the second cache line data retrieved from memory array 130 (and data column group 130d, in particular).

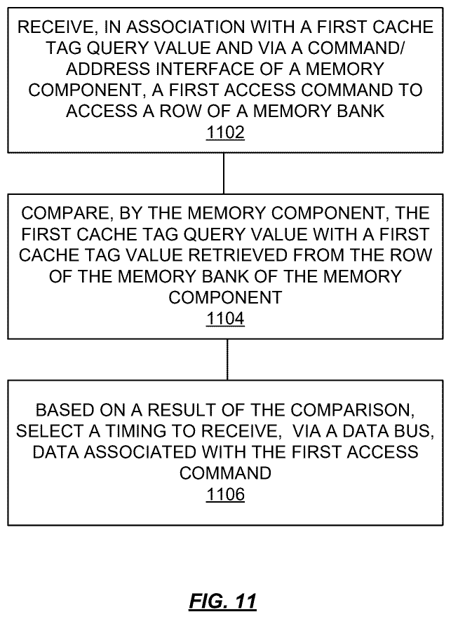

FIG. 9 is a flowchart illustrating a method of operating a memory component to protect cache tag data. One or more steps illustrated in FIG. 9 may be performed by, for example, memory system 100, memory system 500, and/or their components. A first tag value associated with a first cache line in a first plurality of memory elements of a first row of a first set of dynamic random access memory (DRAM) memory array tiles (MATs) (902). For example, controller 120 may command memory device 110 to store a first tag value, that is associated with a first cache line, in a selected row of tags and flags column group 130a. First error detection and correction (EDC) information associated with the first tag value is stored in a second plurality of memory elements of the first row of the first set of DRAM MATs (904). For example, memory device 110 may store EDC information (e.g., generated by tag EDC circuitry 141) protecting the first tag value in the same selected row (i.e., in association with) of tags and flags column group 130a as the first tag value.

The first cache line is stored in a third plurality of memory elements of a second row of a second set of DRAM MATs, the first row and the second row accessed using the same external row address (906). For example, memory device 110 may store the first cache line in in a second row of data column group 130d that is unconnected to the first row in tags and flags column group 130a, but both the first row and the second row are accessed by the same external address.

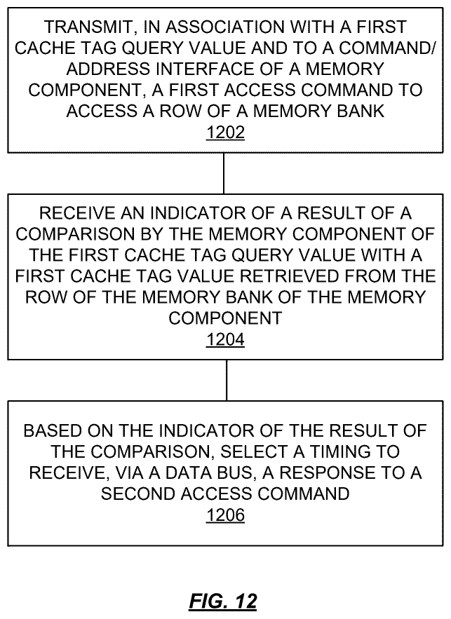

FIG. 10 is a flowchart illustrating a method of varying read access response timing. One or more steps illustrated in FIG. 10 may be performed by, for example, memory system 100, memory system 500, and/or their components. In association with a first cache tag query value and via a command/address interface of a memory component, a first access command to access a row of a memory bank is received (1002). For example, memory device 110 may receive, from controller 120 via CA interface 121 and CA interface 111, a first combined row and column command (e.g., ACTRD) to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command.

By the memory component, the first cache tag query value is compared with the first cache tag value retrieved from the row of the memory bank of the memory component (1004). For example, tag compare circuitry 142 of memory device 110 may compare the first tag value retrieved from memory array 130 at the addressed row and columns with the first tag query value specified by the first command. Based on the result of the comparison, a timing for a response to a second access command to be transmitted via a data bus is selected (1006). For example, as illustrated in FIG. 4C, the timing (T4_{C}) from RD3 to the data associated with RD3 is based on the comparison for RD2 that resulted in a “miss clean” for RD2. In another example, as illustrated in FIG. 4D, the timing (T4_{D}) from RD3 to the data associated with RD3 is based on the comparison for RD1 that resulted in a “hit” for RD1 and thus CLDATA1A and CLDATA1B being placed on the DQ bus and also the comparison for RD2 that resulted in a “miss dirty” for RD2 and thus DCLDATA2A and DCLDATA2B being placed on the DQ bus immediately after CLDATA1B. In another example, as illustrated in FIG. 4F, the timing of, or whether, tags TAG1 are placed on the HM bus is based on the comparison for WR1 that resulted in a “miss dirty” for WR1.

FIG. 11 is a flowchart illustrating a method of varying write access response timing. One or more steps illustrated in FIG. 11 may be performed by, for example, memory system 100, memory system 500, and/or their components. In association with a first cache tag query value and via a command/address interface of a memory component, a first access command to access a row of a memory bank is received (1102). For example, memory device 110 may receive, from controller 120 via CA interface 121 and CA interface 111, a first combined row and column write command (e.g., ACTWR) to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command, and write a cache line to the activated row if the first tag value matches the first tag query value.

By the memory component, the first cache tag query value is compared with the first cache tag value retrieved from the row of the memory bank of the memory component (1004). For example, tag compare circuitry 142 of memory device 110 may compare the first tag value retrieved from memory array 130 at the addressed row and columns with the first tag query value specified by the first command. Based on the result of the comparison, a timing to receive data associated with the first access command via a data bus is selected (1106). For example, as illustrated in FIG. 7, the timing from WR2 to the data associated with WR2 is based on the comparison for WR2 that resulted in a “miss dirty” for WR2. In another example, as illustrated in FIG. 4D, the timing (T4_{D}) from RD3 to the data associated with RD3 is based on the comparison for RD1 that resulted in a “hit” for RD1 and thus CLDATA1A and CLDATA1B being placed on the DQ bus and also the comparison for RD2 that resulted in a “miss dirty” for RD2 and thus DCLDATA2A and DCLDATA2B being placed on the DQ bus immediately after CLDATA1B.

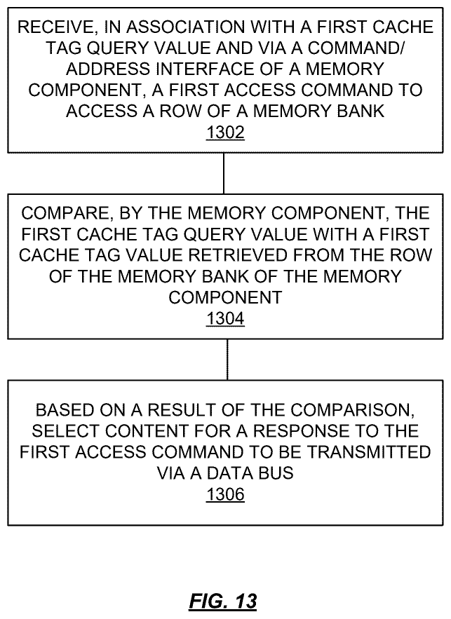

FIG. 12 is a flowchart illustrating a method of receiving cache line data transmitted with variable read access timing. One or more steps illustrated in FIG. 12 may be performed by, for example, memory system 100, memory system 500, and/or their components. In association with a first cache tag query value and to a command/address interface of a memory component, a first access command to access a row of a memory bank is transmitted (1202). For example, controller 120 may transmit, via CA interface 121 and CA interface 111, a first combined row and column command (e.g., ACTRD) for memory device 110 to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command.

An indicator of a result of a comparison by the memory component of the first cache tag query value with a first cache tag value retrieved from the row of the memory bank of the component is received (1204). For example, controller 120 may receive, via HM interface 113 and HM interface 123, an indicator of the result produced by tag compare circuitry 142 of memory device 110 of the first tag value retrieved from memory array 130 with the first tag query value transmitted in association with the first command. Based on the indicator of the result of the comparison, a timing to receive, via a data bus, a response to a second access command is selected (1206). For example, as illustrated in FIG. 4C, the timing (T4_{C}) from RD3 to the data associated with RD3 is based on the comparison for RD2 that resulted in a “miss clean” for RD2. In another example, as illustrated in FIG. 4D, the timing (T4_{D}) from RD3 to the data associated with RD3 is based on the comparison for RD1 that resulted in a “hit” for RD1 and thus CLDATA1A and CLDATA1B being placed on the DQ bus and also the comparison for RD2 that resulted in a “miss dirty” for RD2 and thus DCLDATA2A and DCLDATA2B being placed on the DQ bus immediately after CLDATA1B.

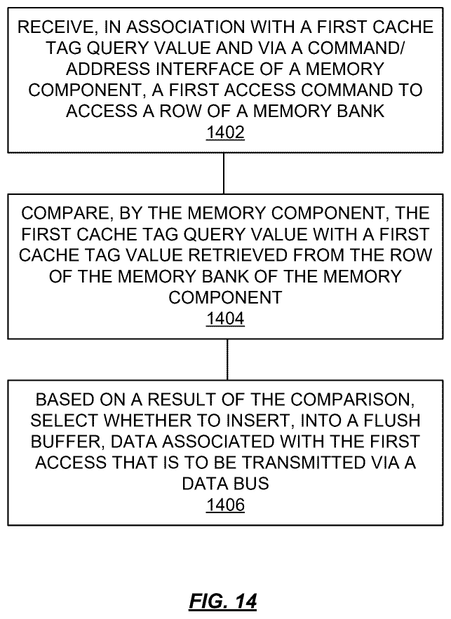

FIG. 13 is a flowchart illustrating a method of varying read access response content. One or more steps illustrated in FIG. 13 may be performed by, for example, memory system 100, memory system 500, and/or their components. In association with a first cache tag query value and via a command/address interface of a memory component, a first access command to access a row of a memory bank is received (1302). For example, memory device 110 may receive, from controller 120 via CA interface 121 and CA interface 111, a first combined row and column command (e.g., ACTRD) to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command.

By the memory component, the first cache tag query value is compared with the first cache tag value retrieved from the row of the memory bank of the memory component (1304). For example, tag compare circuitry 142 of memory device 110 may compare the first tag value retrieved from memory array 130 at the addressed row and columns with the first tag query value specified by the first command. Based on the result of the comparison, content for a response to a second access command to be transmitted via a data bus is selected (1306). For example, as illustrated in FIGS. 3A-3D, the content transmitted via the DQ bus in the case of a “hit” (cache line data) is different from the content transmitted in the case of a “miss clean” (no response), that are both different from the case of a “miss dirty” (dirty cache line data).

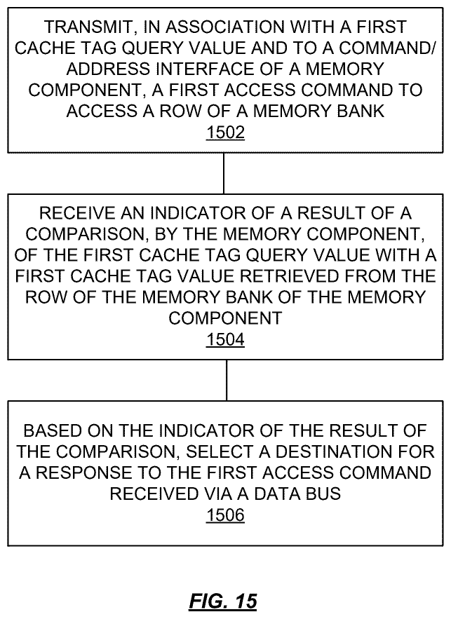

FIG. 14 is a flowchart illustrating a method of managing a flush buffer. One or more steps illustrated in FIG. 14 may be performed by, for example, memory system 100, memory system 500, and/or their components. In association with a first cache tag query value and via a command/address interface of a memory component, a first access command to access a row of a memory bank is received (1402). For example, memory device 510 may receive, from controller 520 via CA interface 521 and CA interface 511, a first combined row and column command (e.g., ACTRD) to activate a first addressed row in memory array 530, read the first set of addressed data columns from column circuitry 532, that comprise at least a first cache tag value (e.g., from tags and flags column group 530a) and a first cache line (e.g., from data column group 530d), from the activated row, and compare a first tag value retrieved from memory array 530 to a first tag query value specified by the first command.

By the memory component, the first cache tag query value is compared with the first cache tag value retrieved from the row of the memory bank of the memory component (1404). For example, tag compare circuitry 542 of memory device 510 may compare the first tag value retrieved from memory array 530 at the addressed row and columns with the first tag query value specified by the first command. Based on a result of the comparison, it is selected whether to insert into a flush buffer data associated with the first access that is to be transmitted via a data bus (1406). For example, as illustrated in FIG. 7, the comparison for WR2 that resulted in a “miss dirty”, is a basis for determining, by memory device 510, whether to insert DCL DATA2A and DCL DATA2B (dirty cache line data) into the flush buffer (e.g., flush buffer 547). In an embodiment, for example, for a read operation, a “miss dirty” may insert data into the flush buffer.

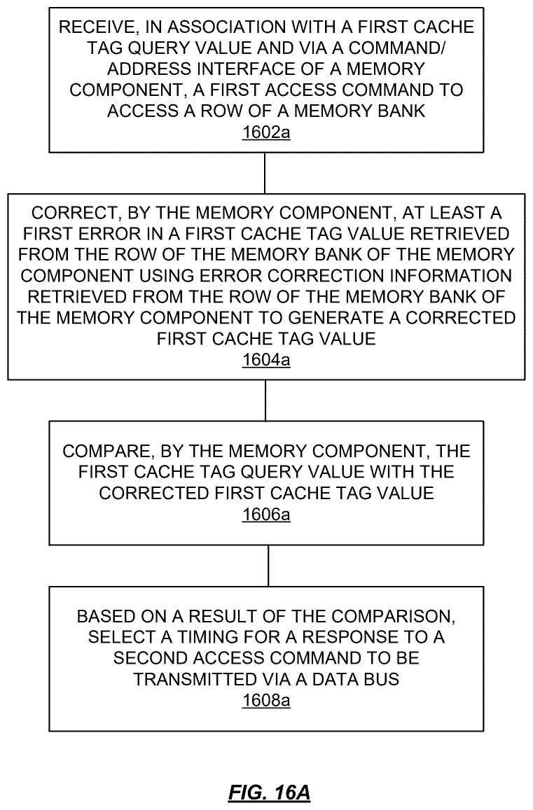

FIG. 15 is a flowchart illustrating a method of operating a memory controller. One or more steps illustrated in FIG. 15 may be performed by, for example, memory system 100, memory system 500, and/or their components. In association with a first cache tag query value and via a command/address interface of a memory component, a first access command to access a row of a memory bank is transmitted (1502). For example, controller 120 may transmit to memory device 110, via CA interface 121 and CA interface 111, a first combined row and column command (e.g., ACTRD or ACTWR) to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command.

An indicator of a result of a comparison, by the memory component, of the first cache tag query value with a first cache tag value retrieved from the row of the memory bank of the memory component is received (1504). For example, a result based on a comparison, by tag compare circuitry 142 of memory device 110, of the first tag value retrieved from memory array 130 at the addressed row and columns with the first tag query value specified by the first command may be received by controller 120 via HM interface 113 and HM interface 123. Based on the indicator of the result of the comparison, a destination for a response to the first access command received via a data bus is selected (1506). For example, based on a “miss dirty” result to a read command, controller 120 may forward the dirty cache line to backing store and/or additional cache levels 150. In another example, based on a “miss clean” result to a write command, controller 120 may forward the write data to both memory device 110 and to backing store and/or additional cache levels 150.

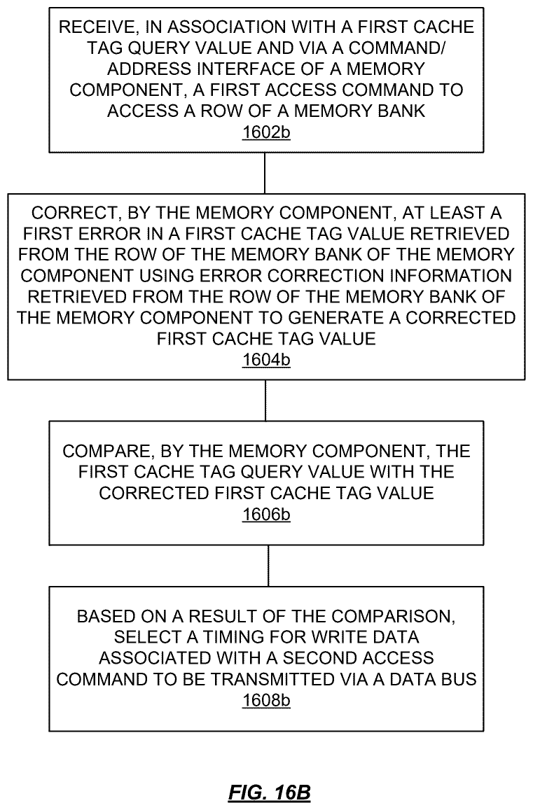

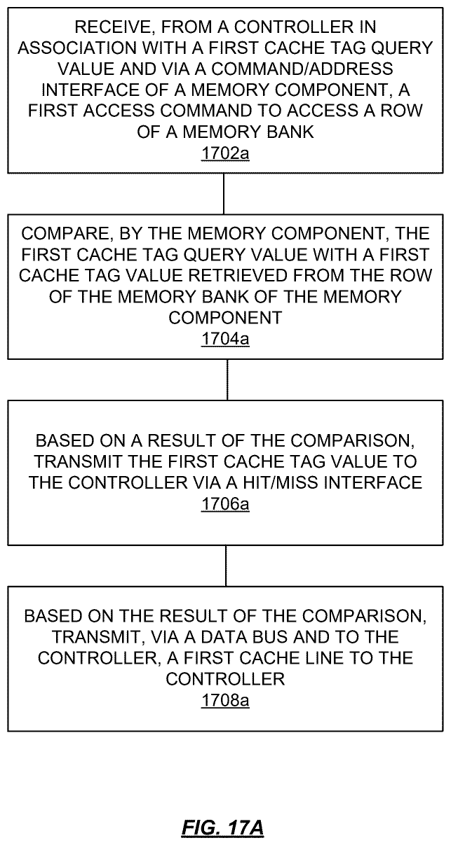

FIG. 16A is a flowchart illustrating a method of correcting a cache tag error. One or more steps illustrated in FIG. 16A may be performed by, for example, memory system 100, memory system 500, and/or their components. In association with a first cache tag query value and via a command/address interface of a memory component, a first access command to access a row of a memory bank is received (1602a). For example, memory device 110 may receive, from controller 120 via CA interface 121 and CA interface 111, a first combined row and column command (e.g., ACTRD) to activate a first addressed row in memory array 130, read the first set of addressed data columns from column circuitry 132, that comprise at least a first cache tag value (e.g., from tags and flags column group 130a), first tag EDC information (e.g., from tag EDC information column group 130b) and a first cache line (e.g., from data column group 130d), from the activated row, and compare a first tag value retrieved from memory array 130 to a first tag query value specified by the first command.

By the memory component, at least a first error is corrected in a first cache tag value retrieved from the row of the memory bank of the memory component using error correction information retrieved from the row of the memory bank of the memory component to generate a corrected first cache tag value (1604a). For example, tag EDC circuitry of memory device 110 may use the first tag EDC information to correct at least one error in the first tag value retrieved from memory array 130 to generate a corrected first tag value. By the memory component, the first cache tag query value is compared with the corrected first cache tag value (1606a). For example, tag compare circuitry 142 of memory device 110 may compare the corrected first tag value received from tag EDC circuitry 141 the first tag query value specified by the first command. Based on the result of the comparison, a timing for a response to a second access command to be transmitted via a data bus is selected (1608a). For example, as illustrated in FIG. 4C, for a read operation the timing (T4_{C}) from RD3 to the data associated with RD3 is based on the comparison for RD2 that resulted in a “miss clean” for RD2.

FIG. 16B is a flowchart illustrating a method of correcting a cache tag error. One or more steps illustrated in FIG. 16B may be performed by, for example, memory system 100, memory system 500, and/or their components. In association with a first cache tag query value and via a command/address interface of a memory component, a first access command to access a row of a memory bank is received (1602b). For example, memory device 110 may receive, from controller 120 via CA interface 121 and CA interface 111, a first combined row and column command (e.g., ACTWR) to activate a first addressed row in memory array 130, read the first set of addressed data columns from column circuitry 132, that comprise at least a first cache tag value (e.g., from tags and flags column group 130a), first tag EDC information (e.g., from tag EDC information column group 130b) and a first cache line (e.g., from data column group 130d), from the activated row, and compare a first tag value retrieved from memory array 130 to a first tag query value specified by the first command.

By the memory component, at least a first error is corrected in a first cache tag value retrieved from the row of the memory bank of the memory component using error correction information retrieved from the row of the memory bank of the memory component to generate a corrected first cache tag value (1604b). For example, tag EDC circuitry of memory device 110 may use the first tag EDC information to correct at least one error in the first tag value retrieved from memory array 130 to generate a corrected first tag value. By the memory component, the first cache tag query value is compared with the corrected first cache tag value (1606b). For example, tag compare circuitry 142 of memory device 110 may compare the corrected first tag value received from tag EDC circuitry 141 the first tag query value specified by the first command. Based on the result of the comparison, a timing for write data associated with a second access command to be transmitted via a data bus is selected (1608b). For example, as illustrated in FIG. 4E, for a write operation the timing (T4_{E}) from WR3 to the data associated with WR3 is based on the comparison for WR2 that resulted in a “hit clean” for WR2.

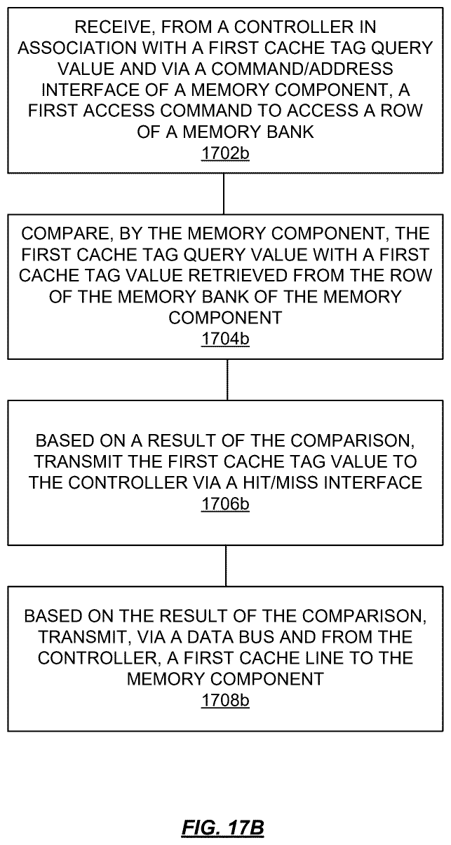

FIG. 17A is a flowchart illustrating a method of responding to a dirty miss. One or more steps illustrated in FIG. 17A may be performed by, for example, memory system 100, memory system 500, and/or their components. From a controller and in association with a first cache tag query value and via a command/address interface of a memory component, a first access command to access a row of a memory bank is received (1702a). For example, memory device 110 may receive, from controller 120 via CA interface 121 and CA interface 111, a first combined row and column command (e.g., ACTRD or ACTWR) to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command.

By the memory component, the first cache tag query value is compared with the first cache tag value retrieved from the row of the memory bank of the memory component (1704a). For example, tag compare circuitry 142 of memory device 110 may compare the first tag value retrieved from memory array 130 at the addressed row and columns with the first tag query value specified by the first command. Based on a result of the comparison, the first cache tag value is transmitted to the controller via a hit/miss interface (1706a). For example, based on a tag comparison by tag compare circuitry 142 that results in a “miss dirty”, memory device may transmit, via HM interface 113 and HM interface 123 the first tag value retrieved from memory array 130. Based on a result of the comparison, the first cache line is transmitted to the controller via a data bus (1708a). For example, for a read operation, based on a tag comparison by tag compare circuitry 142 that results in a “miss dirty”, memory device may transmit, via DQ interface 112 and DQ interface 122 the first cache line retrieved from memory array 130.

FIG. 17B is a flowchart illustrating a method of responding to a dirty miss. One or more steps illustrated in FIG. 17A may be performed by, for example, memory system 100, memory system 500, and/or their components. From a controller and in association with a first cache tag query value and via a command/address interface of a memory component, a first access command to access a row of a memory bank is received (1702b). For example, memory device 110 may receive, from controller 120 via CA interface 121 and CA interface 111, a first combined row and column command (e.g., ACTRD or ACTWR) to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command.

By the memory component, the first cache tag query value is compared with the first cache tag value retrieved from the row of the memory bank of the memory component (1704b). For example, tag compare circuitry 142 of memory device 110 may compare the first tag value retrieved from memory array 130 at the addressed row and columns with the first tag query value specified by the first command. Based on a result of the comparison, the first cache tag value is transmitted to the controller via a hit/miss interface (1706b). For example, based on a tag comparison by tag compare circuitry 142 that results in a “miss dirty”, memory device may transmit, via HM interface 113 and HM interface 123 the first tag value retrieved from memory array 130. Based on a result of the comparison, the first cache line is transmitted from the controller via a data bus to the memory component (1708b). For example, for a write operation, based on a tag comparison by tag compare circuitry 142 that results in a “miss dirty”, controller 120 device may transmit, via DQ interface 112 and DQ interface 122 the first cache line to memory component 110.

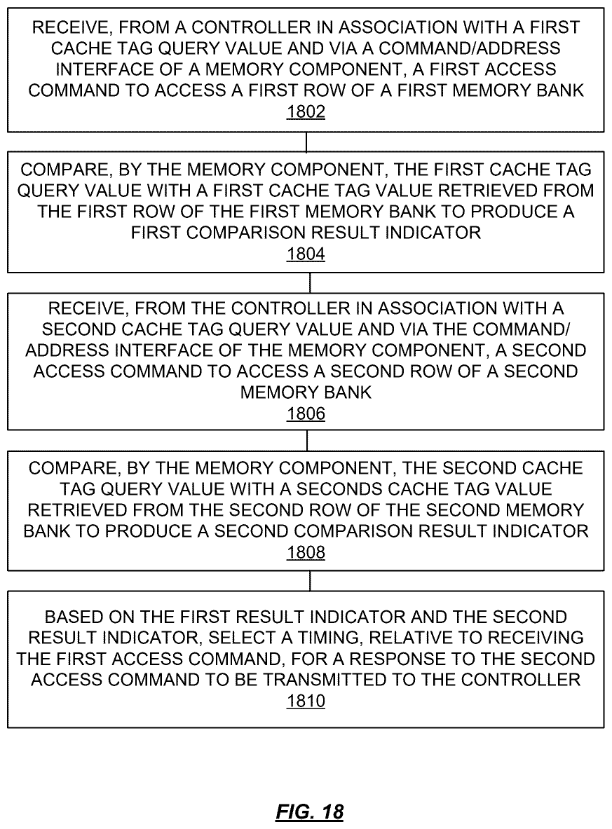

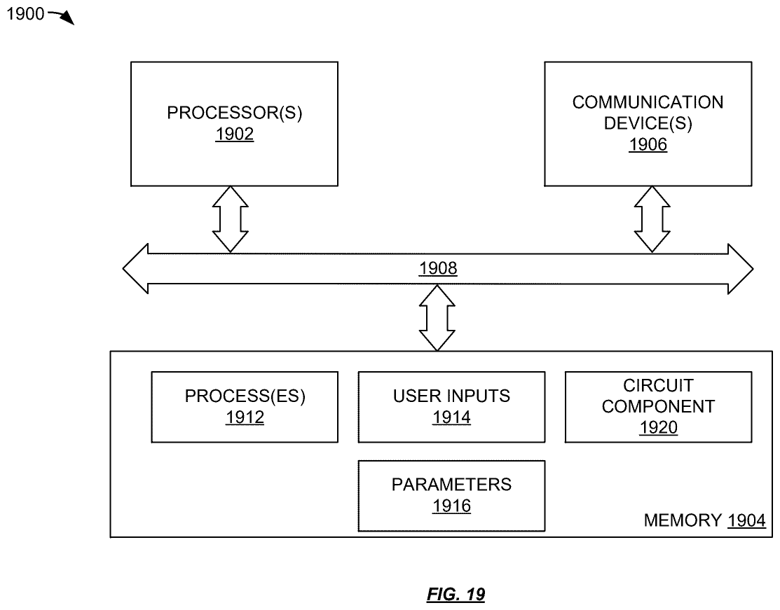

FIG. 18 is a flowchart illustrating a method of varying access response timing.

One or more steps illustrated in FIG. 18 may be performed by, for example, memory system 100, memory system 500, and/or their components. In association with a first cache tag query value and via a command/address interface of a memory component, a first access command to access a first row of a memory bank is received (1802). For example, memory device 110 may receive, from controller 120 via CA interface 121 and CA interface 111, a first combined row and column command (e.g., ACTRD) to activate a first addressed row in memory array 130, read the first set of addressed data columns from column circuitry 132, that comprise at least a first cache tag value (e.g., from tags and flags column group 130a) and a first cache line (e.g., from data column group 130d), from the activated row, and compare a first tag value retrieved from memory array 130 to a first tag query value specified by the first command.

By the memory component, the first cache tag query value is compared with the first cache tag value retrieved from the first row of the memory bank to produce a first comparison result indicator (1804). For example, tag compare circuitry 142 of memory device 110 may compare the first tag value retrieved from memory array 130 at the first addressed row and columns with the first tag query value specified by the first command to produce a first hit or miss indicator. In association with a second cache tag query value and via the command/address interface of the memory component, a second access command to access a second row of a memory bank is received (1806). For example, memory device 110 may receive, from controller 120 via CA interface 121 and CA interface 111, a second combined row and column command (e.g., ACTRD) to activate a second addressed row in memory array 130, read the second set of addressed data columns from column circuitry 132, that comprise at least a second cache tag value (e.g., from tags and flags column group 130a) and a second cache line (e.g., from data column group 130d), from the activated row, and compare a second tag value retrieved from memory array 130 to a second tag query value specified by the second command.

By the memory component, the second cache tag query value is compared with the second cache tag value retrieved from the second row of the memory bank to produce a second comparison result indicator (1808). For example, tag compare circuitry 142 of memory device 110 may compare the second tag value retrieved from memory array 130 at the second addressed row and columns with the second tag query value specified by the second command to produce a second hit or miss indicator. Based on the first result indicator and the second result indicator, a timing for a response to a second access command to be transmitted via a data bus is selected (1810). For example, as illustrated in FIG. 4B, the timing (T4_{b}) from RD3 to the data associated with RD3 (CL DATA3A) is based on the comparison for RD2 that resulted in a “hit” for RD2 and is also based on the comparison for RD3 that resulted in a “hit” for RD3.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of memory system 100, memory system 500, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

FIG. 19 is a block diagram illustrating one embodiment of a processing system 1900 for including, processing, or generating, a representation of a circuit component 1920. Processing system 1900 includes one or more processors 1902, a memory 1904, and one or more communications devices 1906. Processors 1902, memory 1904, and communications devices 1906 communicate using any suitable type, number, and/or configuration of wired and/or wireless connections 1908.

Processors 1902 execute instructions of one or more processes 1912 stored in a memory 1904 to process and/or generate circuit component 1920 responsive to user inputs 1914 and parameters 1916. Processes 1912 may be any suitable electronic design automation (EDA) tool or portion thereof used to design, simulate, analyze, and/or verify electronic circuitry and/or generate photomasks for electronic circuitry. Representation 1920 includes data that describes all or portions of memory system 100, memory system 500, and their components, as shown in the Figures.

Representation 1920 may include one or more of behavioral, register transfer, logic component, transistor, and layout geometry-level descriptions. Moreover, representation 1920 may be stored on storage media or communicated by carrier waves.

Data formats in which representation 1920 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email

User inputs 1914 may comprise input parameters from a keyboard, mouse, voice recognition interface, microphone and speakers, graphical display, touch screen, or other type of user interface device. This user interface may be distributed among multiple interface devices. Parameters 1916 may include specifications and/or characteristics that are input to help define representation 1920. For example, parameters 1916 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 1904 includes any suitable type, number, and/or configuration of non-transitory computer-readable storage media that stores processes 1912, user inputs 1914, parameters 1916, and circuit component 1920.

Communications devices 1906 include any suitable type, number, and/or configuration of wired and/or wireless devices that transmit information from processing system 1900 to another processing or storage system (not shown) and/or receive information from another processing or storage system (not shown). For example, communications devices 1906 may transmit circuit component 1920 to another system. Communications devices 1906 may receive processes 1912, user inputs 1914, parameters 1916, and/or circuit component 1920 and cause processes 1912, user inputs 1914, parameters 1916, and/or circuit component 1920 to be stored in memory 1904.

Implementations discussed herein include, but are not limited to, the following examples:

Example 1: A memory component, comprising: dynamic random access memory (DRAM) array to store a plurality of cache information entries, each cache information entry comprising a tag field, a cache line, and at least one flag; a command/address interface to receive a first access command, in association with a first tag query value, to access a first cache information entry comprising a first tag value, a first cache line, and a first flag; a cache result interface to transmit a first status indicator to a controller, the first status indicator including a first hit/miss indication indicating whether the first tag query value matches the first tag value; and a data interface to communicate cache lines with the controller, the first status indicator also indicating to the controller a content of a response to the first access command communicated via the data interface.

Example 2: The memory component of example 1, wherein the first status indicator at least indicates whether the first cache information entry corresponds to a valid cache information entry, whether the first tag query value matches the first tag value, whether the first tag query value does not match the first tag value where the first cache line has not been modified, and whether the first tag query value does not match the first tag value where the first cache line has been modified.

Example 3: The memory component of example 2, wherein when a first status indicator indicates the first cache information entry is valid and the first tag query value matched the first tag value, the content of the response to the first access command communicated via the data interface includes the first cache line.

Example 4: The memory component of example 2, wherein when the first status indicator indicates the first cache information entry is valid and the first tag query value does not match the first tag value where the first cache line has not been modified, the content of the response to the first access command communicated via the data interface is empty.

Example 5: The memory component of example 2, wherein when the first status indicator indicates the first cache information entry is valid and the first tag query value does not match the first tag value where the first cache line has been modified, the response to the first access command communicated via the data interface includes the first cache line.

Example 6: The memory component of example 2, wherein when the first status indicator indicates the first cache information entry is valid and the first tag query value does not match the first tag value where the first cache line has been modified, the cache result interface is to further transmit the first tag value.

Example 7: The memory component of example 1, wherein each cache information entry further comprises error detect and correct information dedicated to protecting the tag field.

Example 8: A memory component, comprising: a command/address interface to receive a first access command, in association with a first tag query value, to access a first cache information entry; dynamic random access memory (DRAM) array to store the first cache information entry, the first cache information entry comprising a first tag value, a first cache line, and a first at least one flag; a data interface to communicate the first cache line with a controller; and a cache result interface to transmit, in response to the first access command, a first status indicator to a controller, the first status indicator to indicate that the first tag query value matches the first tag value and that the data interface is to communicate the first cache line with the controller.

Example 9: The memory component of example 8, wherein the command/address interface is to receive a second access command, in association with a second tag query value, to access a second cache information entry, the second cache information entry comprising a second tag value, a second cache line, and a second at least one flag; and the cache result interface is to transmit, in response to the second access command, a second status indicator to the controller, the second status indicator to indicate that the second tag query value does not match the second tag value and that the data interface is not to communicate the second cache line with the controller.

Example 10: The memory component of example 8, wherein the command/address interface is to receive a second access command, in association with a second tag query value, to access a second cache information entry, the second cache information entry comprising a second tag value, a second cache line, and a second at least one flag; and the cache result interface is to transmit, in response to the second access command, a second status indicator to the controller, the second status indicator to indicate that the second tag query value does not match the second tag value and that the data interface is to communicate the second cache line with the controller.

Example 11: The memory component of example 10, wherein the second status indicator is to indicate the cache result interface is to communicate second tag value.

Example 12: The memory component of example 8, wherein the memory component of example 8 comprises a plurality of stacked DRAM dies.

Example 13: The memory component of example 10, wherein the first status indicator indicates a first timing for the data interface to communicate the first cache line with the controller.

Example 14: The memory component of example 13, wherein the second status indicator indicates a second timing for the data interface to communicate the second cache line with the controller.

Example 15: A method of operating a memory component, comprising: receiving, in association with a first cache tag query value and via a command/address interface, a first access command to access a first cache information entry stored by a dynamic random access memory (DRAM) array, the first cache information entry comprising a first cache tag value and a first cache line; comparing, by the memory component, the first cache tag query value with the first cache tag value to produce a first comparison result; transmitting, by the memory component, a cache hit indicator that is based on the first comparison result; based on the first comparison result, transmitting, via a data interface, the first cache line; receiving, in association with a second cache tag query value and via the command/address interface, a second access command to access a second cache information entry stored by the DRAM array, the second cache information entry comprising a second cache tag value and a second cache line; comparing, by the memory component, the second cache tag query value with the second cache tag value to produce a second comparison result; transmitting, by the memory component, a cache miss dirty indicator that is based on the second comparison result; and based on the second comparison result, transmitting, via the data interface, the second cache line.

Example 16: The method of example 15, further comprising: receiving, in association with a third cache tag query value and via the command/address interface, a third access command to access a third cache information entry stored by the DRAM array, the third cache information entry comprising a third cache tag value and a third cache line; comparing, by the memory component, the third cache tag query value with the third cache tag value to produce a third comparison result; transmitting, by the memory component, a cache clean miss indicator that is based on the third comparison result; and based on the third comparison result, not transmitting, via the data interface, the third cache line.

Example 17: The method of example 15, wherein the cache hit indicator is transmitted before the data interface begins transmitting the first cache line.

Example 18: The method of example 15, wherein the cache hit indicator is transmitted via a cache result interface of the memory component.

Example 19: The method of example 15, further comprising: transmitting the second cache tag value.

Example 20: The method of example 15, wherein the cache hit indicator is transmitted via a cache result interface of the memory component, the method further comprising: transmitting, via the cache result interface, the second cache tag value.

Example 21: A memory component, comprising: a first dynamic random access memory (DRAM) array having memory element rows and memory element columns; a first plurality of memory element columns to store data associated with a first plurality of cache lines; a second plurality of memory element columns to store first cache tag values respectively associated with each of the first plurality of cache lines; a third plurality of memory element columns to store error detection and correction (EDC) information associated with the first cache tag values; and tag comparison circuitry to compare tag values from the second plurality of memory element columns with first tag query values received by the memory component in association with first respective access commands.

Example 22: The memory component of example 21, further comprising: a fourth plurality of memory element columns to store EDC information associated with the first plurality of memory element columns.

Example 23: The memory component of example 21, further comprising: a second DRAM array having memory element rows and memory element columns; a fourth plurality of memory element columns to store data associated with a second plurality of cache lines; a fifth plurality of memory element columns to store second cache tag values respectively associated with each of the second plurality of cache lines; a sixth plurality of memory element columns to store EDC information associated with the second cache tag values; and the tag comparison circuitry to compare tag values from the fifth plurality of memory element columns with second tag query values received by the memory component in association with second respective access commands.

Example 24: The memory component of example 23, further comprising: tag column selection logic to provide the tag values from the second plurality of memory element columns to the tag comparison circuitry.

Example 25: The memory component of example 24, wherein the tag column selection logic is to provide the tag values from the second plurality of memory element columns to the tag comparison circuitry based on column addresses received in association with the first respective access commands.

Example 26: The memory component of example 25, further comprising: data column selection logic to provide the cache lines from the first plurality of memory element columns to output circuitry.

Example 27: A method of operating a memory component, comprising: storing a first tag value associated with a first cache line in a first plurality of memory elements of a first row of a first set of dynamic random access memory (DRAM) memory array tiles (MATs); storing first error detection and correction (EDC) information associated with the first tag value in a second plurality of memory elements of the first row of the first set of DRAM MATs; and storing the first cache line in a third plurality of memory elements of a second row of a second set of DRAM MATs, the first row and the second row accessed using a same external row address.

Example 28: The method of example 27, further comprising: receiving a first tag query value in association with a first access command that is directed to accessing the first row and the second row; receiving the first tag value from the first plurality of memory elements; receiving the first EDC information from a second plurality of memory elements; and based on the first tag value received from the first plurality of memory elements and the first EDC information received from the second plurality of memory elements, determining whether the first tag value from the first plurality of memory elements has an error.

Example 29: The method of example 28, further comprising: correcting an error in the first tag value to generate a corrected tag value; and comparing the corrected tag value with the first tag query value to produce a first comparison result.

Example 30: The method of example 29, further comprising: based on the first comparison result, transmitting a hit/miss indication to a controller.

Example 31: The method of example 30, further comprising: based on the first comparison result, transmitting a data bus content indication to the controller.

Example 32: The method of example 31, further comprising: based on the first comparison result, transmitting the first cache line to the controller.

Example 33: The method of example 32, further comprising: based on the first comparison result, transmitting the first tag value to the controller.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A memory component, comprising:
dynamic random access memory (DRAM) array to store a plurality of cache information entries, each cache information entry comprising a tag field, a cache line, and at least one flag;
a command/address interface to receive a first access command, in association with a first tag query value, to access a first cache information entry comprising a first tag value, a first cache line, and a first flag;
a cache result interface to transmit a first status indicator to a controller, the first status indicator including a first hit/miss indication indicating whether the first tag query value matches the first tag value; and
a data interface to communicate cache lines with the controller, the first status indicator also indicating to the controller a content of a response to the first access command communicated via the data interface.

2. The memory component of claim 1, wherein the first status indicator at least indicates whether the first cache information entry corresponds to a valid cache information entry, whether the first tag query value matches the first tag value, whether the first tag query value does not match the first tag value where the first cache line has not been modified, and whether the first tag query value does not match the first tag value where the first cache line has been modified.

3. The memory component of claim 2, wherein when a first status indicator indicates the first cache information entry is valid and the first tag query value matched the first tag value, the content of the response to the first access command communicated via the data interface includes the first cache line.

4. The memory component of claim 2, wherein when the first status indicator indicates the first cache information entry is valid and the first tag query value does not match the first tag value where the first cache line has not been modified, the content of the response to the first access command communicated via the data interface is empty.

5. The memory component of claim 2, wherein when the first status indicator indicates the first cache information entry is valid and the first tag query value does not match the first tag value where the first cache line has been modified, the response to the first access command communicated via the data interface includes the first cache line.

6. The memory component of claim 2, wherein when the first status indicator indicates the first cache information entry is valid and the first tag query value does not match the first tag value where the first cache line has been modified, the cache result interface is to further transmit the first tag value.

7. The memory component of claim 1, wherein each cache information entry further comprises error detect and correct information dedicated to protecting the tag field.

8. A memory component, comprising:
a command/address interface to receive a first access command, in association with a first tag query value, to access a first cache information entry;
dynamic random access memory (DRAM) array to store the first cache information entry, the first cache information entry comprising a first tag value, a first cache line, and a first at least one flag;
a data interface to communicate the first cache line with a controller; and
a cache result interface to transmit, in response to the first access command, a first status indicator to a controller, the first status indicator to indicate that the first tag query value matches the first tag value and that the data interface is to communicate the first cache line with the controller.

9. The memory component of claim 8, wherein the command/address interface is to receive a second access command, in association with a second tag query value, to access a second cache information entry, the second cache information entry comprising a second tag value, a second cache line, and a second at least one flag; and
the cache result interface is to transmit, in response to the second access command, a second status indicator to the controller, the second status indicator to indicate that the second tag query value does not match the second tag value and that the data interface is not to communicate the second cache line with the controller.

10. The memory component of claim 8, wherein the command/address interface is to receive a second access command, in association with a second tag query value, to access a second cache information entry, the second cache information entry comprising a second tag value, a second cache line, and a second at least one flag; and
the cache result interface is to transmit, in response to the second access command, a second status indicator to the controller, the second status indicator to indicate that the second tag query value does not match the second tag value and that the data interface is to communicate the second cache line with the controller.

11. The memory component of claim 10, wherein the second status indicator is to indicate the cache result interface is to communicate second tag value.

12. The memory component of claim 8, wherein the memory component of claim 8 comprises a plurality of stacked DRAM dies.

13. The memory component of claim 10, wherein the first status indicator indicates a first timing for the data interface to communicate the first cache line with the controller.

14. The memory component of claim 13, wherein the second status indicator indicates a second timing for the data interface to communicate the second cache line with the controller.

15. A method of operating a memory component, comprising:
receiving, in association with a first cache tag query value and via a command/address interface, a first access command to access a first cache information entry stored by a dynamic random access memory (DRAM) array, the first cache information entry comprising a first cache tag value and a first cache line;
comparing, by the memory component, the first cache tag query value with the first cache tag value to produce a first comparison result;
transmitting, by the memory component, a cache hit indicator that is based on the first comparison result;
based on the first comparison result, transmitting, via a data interface, the first cache line;
receiving, in association with a second cache tag query value and via the command/address interface, a second access command to access a second cache information entry stored by the DRAM array, the second cache information entry comprising a second cache tag value and a second cache line;
comparing, by the memory component, the second cache tag query value with the second cache tag value to produce a second comparison result;
transmitting, by the memory component, a cache miss dirty indicator that is based on the second comparison result; and
based on the second comparison result, transmitting, via the data interface, the second cache line.

16. The method of claim 15, further comprising:
receiving, in association with a third cache tag query value and via the command/address interface, a third access command to access a third cache information entry stored by the DRAM array, the third cache information entry comprising a third cache tag value and a third cache line;
comparing, by the memory component, the third cache tag query value with the third cache tag value to produce a third comparison result;
transmitting, by the memory component, a cache clean miss indicator that is based on the third comparison result; and
based on the third comparison result, not transmitting, via the data interface, the third cache line.

17. The method of claim 15, wherein the cache hit indicator is transmitted before the data interface begins transmitting the first cache line.

18. The method of claim 15, wherein the cache hit indicator is transmitted via a cache result interface of the memory component.

19. The method of claim 15, further comprising:
transmitting the second cache tag value.

20. The method of claim 15, wherein the cache hit indicator is transmitted via a cache result interface of the memory component, the method further comprising:
transmitting, via the cache result interface, the second cache tag value.

21-33. (canceled)
